(19) United States
(12) Patent Application Publication
(10) Pub. No.: US 2026/0215111 A1
(43) Pub. Date: Jul. 23, 2026

(54) DISPLAY DEVICE AND ELECTRONIC DEVICE INCLUDING THE SAME

(71) Applicant: Samsung Display Co., LTD., Yongin-si (KR)

(72) Inventors: Do Yeong PARK, Yongin-si (KR); Dong Hee SHIN, Yongin-si (KR)

(21) Appl. No.: 19/374,239

(22) Filed: Oct. 30, 2025

(30) Foreign Application Priority Data
Jan. 21, 2025 (KR) 10-2025-0008863

(51) Int. Cl. H10K 59/131; G09G 3/3266

(52) U.S. Cl. CPC H10K 59/131; G09G 3/3266; G09G 2300/0819; G09G 2300/0842; G09G 2310/0286; G09G 2310/08; G09G 2320/0247; G09G 2340/0435

(57) ABSTRACT

A display device includes clock wirings arranged in a first direction, where each of the clock wirings includes a first metal layer and a second metal layer vertically overlapping the first metal layer, and clock signals are input to the clock wirings, side signal wirings including the first metal layer extending in a second direction, and located adjacent to the clock wirings in the first direction, and stage circuits located adjacent to the side signal wirings in the first direction, and connected to the clock wirings and the side signal wirings. The second metal layer of at least one of the clock wirings is bent at least once in a third direction opposite to the first direction to overlap an opening defined through the first metal layer.

This application claims priority to Korean Patent Application No. 10-2025-0008863, filed on Jan. 21, 2025, and all the benefits accruing therefrom under 35 U.S.C. § 119, the content of which in its entirety is herein incorporated by reference.

### BACKGROUND

### 1. Field

Embodiments of the present disclosure relate to a display device and an electronic device including the display device.

### 2. Description of the Related Art

With the development of information technology, the importance of a display device, which is a connection medium between a user and information, is being highlighted. Accordingly, the use of display devices such as liquid crystal display devices and organic light-emitting display devices is increasing.

The display device may be capable of displaying an image at various refresh frame rates. However, changes in luminance may be recognized in such a process.

In addition, the display device can provide a natural image by lowering the resolution and increasing the refresh frame rate according to the user's selection, or can provide a high-definition image by increasing the resolution and lowering the refresh frame rate.

While providing the above functions, there is a growing need to provide a display device having a narrow bezel.

### SUMMARY

Embodiments of the present disclosure provide a display device capable of improving visibility, displaying images at various refresh frame rates, and providing a narrow bezel, and an electronic device including the display device.

Embodiments of the present disclosure provide a display device including clock wirings arranged in a first direction, where each of the clock wirings includes a first metal layer and a second metal layer vertically overlapping the first metal layer, and clock signals are input to the clock wirings, side signal wirings including the first metal layer extending in a second direction crossing the first direction, and located adjacent to the clock wirings in the first direction, and stage circuits located adjacent to the side signal wirings in the first direction, and connected to the clock wirings and the side signal wirings, where the second metal layer of at least one of the clock wirings is bent at least once in a third direction opposite to the first direction to overlap an opening defined through the first metal layer.

In an embodiment, an N-th (N is an integer greater than or equal to 1) stage circuit of the stage circuits may include an N-th scan driving integrated circuit, and an N-th sense driving integrated circuit. In such an embodiment, the clock wirings may include first to sixth clock wirings connected to the N-th stage circuit, and thirteenth to eighteenth clock wirings connected to the N-th stage circuit.

In an embodiment, the first to sixth clock wirings may be sequentially arranged in the first direction to be adjacent to each other. In such an embodiment, the second metal layer of the first clock wiring may extend in the second direction, be bent for a first time, and extend in the first direction.

In an embodiment, the second metal layer of the third clock wiring may extend in the second direction and be bent for a first time to extend in the third direction, extend in the third direction and be bent for a second time to extend in the second direction, and extend in the second direction and be bent for a third time to extend in the first direction.

In an embodiment, a region of the second metal layer of the third clock wiring which is bent for the second time and extends in the second direction, may vertically overlap an opening defined through the first metal layer of the second clock wiring.

In an embodiment, the second metal layer of the fifth clock wiring may extend in the second direction and be bent for a first time to extend in the third direction, extend in the third direction and be bent for a second time to extend in the second direction, and extend in the second direction and be bent for a third time to extend in the first direction.

In an embodiment, a region of the second metal layer of the third clock wiring which is bent for the first time and extends in the third direction, and a region of the second metal layer of the fifth clock wiring which is bent for the first time and extends in the third direction may be located adjacent to each other in the first direction.

In an embodiment, a region of the second metal layer of the fifth clock wiring which is bent for the second time and extends in the second direction may vertically overlap an opening defined through the first metal layer of the third clock wiring.

In an embodiment, a length of a region of the second metal layer of the first clock wiring which is bent for the first time and extends in the first direction may be the same as a sum of a length of a region of the second metal layer of the third clock wiring which is bent for the first time and extends in the third direction, and a length of a region of the second metal layer of the third clock wiring which is bent for the third time and extends in the first direction.

In an embodiment, the second metal layer of the second clock wiring may extend in a direction opposite to the second direction, be bent for a first time, and extend in the second direction.

In an embodiment, an (N+1)-th stage circuit among the above stage circuits may include an (N+1)-th scan driving integrated circuit, and an (N+1)-th sense driving integrated circuit. In such an embodiment, the clock wirings may further include seventh to twelfth clock wirings connected to the (N+1)-th stage circuit, and nineteenth to twenty-fourth clock wirings connected to the (N+1)-th stage circuit.

In an embodiment, the stage circuits may include a plurality of output buffers which outputs the clock signals input to the clock wirings. In such an embodiment, at least two of transistors for controlling each of the plurality of output buffers may be controlled in response to a voltage applied to one node.

Embodiments of the present disclosure provide an electronic device including a host which outputs a control signal and first image data, and a display device which displays an image based on the control signal and the first image data, where the display device includes clock wirings sequentially arranged in a first direction, where each of the clock wirings includes a first metal layer and a second metal layer vertically overlapping the first metal layer, and clock signals provided based on the control signal are input to the clock wirings, side signal wirings including the first metal layer extending in a second direction crossing the first direction, and located adjacent to the clock wirings in the first direction, and stage circuits located adjacent to the side signal wirings in the first direction, and connected to the clock wirings and the side signal wirings, where the second metal layer of at least one of the clock wirings is bent at least once in a third direction opposite to the first direction to overlap an opening defined through the first metal layer.

Embodiments of the present disclosure provide a display device including clock wirings sequentially arranged in a first direction, where each of the clock wirings includes a first metal layer and a second metal layer vertically overlapping the first metal layer, and clock signals are input to the clock wirings, side signal wirings including the first metal layer extending in a second direction crossing the first direction, and located adjacent to the clock wirings in the first direction, and stage circuits located adjacent to the side signal wirings in the first direction, and connected to the clock wirings and the side signal wirings, where a first clock wiring of the clock wirings has a first longitudinal width, and a second clock wiring of the clock wirings, which is located closer to the stage circuits than the first clock wiring is, has a second longitudinal width which is smaller than the first longitudinal width.

In an embodiment, an N-th (N is an integer greater than or equal to 1) stage circuit of the stage circuits may include an N-th scan driving integrated circuit, and an N-th sense driving integrated circuit. In such an embodiment, the clock wirings may include first and second clock wirings connected to the N-th stage circuit, and thirteenth and fourteenth clock wirings connected to the N-th stage circuit.

In an embodiment, the second metal layer of each of the first clock wiring and the second clock wiring may extend in the second direction and be bent for a first time to extend in the first direction. In such an embodiment, a length of a region in which the first clock wiring extends in the second direction may be longer than a length of a region in which the second clock wiring extends in the second direction.

In an embodiment, a region in which the first clock wiring extends in the first direction may have a first longitudinal width. In such an embodiment, a region in which the second clock wiring extends in the first direction may have the second longitudinal width.

In an embodiment, the second metal layer of each of the thirteenth clock wiring and the fourteenth clock wiring may extend in the second direction and be bent for a first time to extend in the first direction. In such an embodiment, a length of a region in which the thirteenth clock wiring extends in the first direction may be longer than a length of a region in which the fourteenth clock wiring extends in the first direction.

In an embodiment, a region in which the thirteenth clock wiring extends in the first direction may have the first longitudinal width. In such an embodiment, a region in which the fourteenth clock wiring extends in the first direction may have the second longitudinal width.

In an embodiment, one of the side signal wirings may have a first lateral width in a region overlapping the first clock wiring of the clock wirings, and have a second lateral width larger than the first lateral width in a region overlapping the second clock wiring of the clock wirings.

### BRIEF DESCRIPTION OF THE DRAWINGS

The above and other features of the disclosure will become more apparent by describing in further detail embodiments thereof with reference to the accompanying drawings, in which:

FIG. 1 is a block diagram of a display device according to embodiments of the present disclosure;

FIG. 2 is a block diagram of a display area according to embodiments of the present disclosure;

FIG. 3 is a circuit diagram illustrating an example of a sub-pixel according to embodiments of the present disclosure;

FIG. 4 is a diagram illustrating a sensing circuit in embodiments of the present disclosure;

FIGS. 5A, 5B, and 5C are signal diagrams illustrating examples of a driving method in which the display device of FIG. 1 displays images at different frame rates;

FIG. 6A is a signal timing diagram illustrating an example of the first refresh frame rate;

FIG. 6B is a signal timing diagram illustrating an example of the second refresh frame rate;

FIG. 7 is a block diagram of an embodiment of a scan driving circuit;

FIG. 8 is an equivalent circuit diagram of a scan driving integrated circuit according to an embodiment;

FIG. 9 is a block diagram of an embodiment of a sense driving circuit;

FIG. 10 is an equivalent circuit diagram of a sense driving integrated circuit according to an embodiment;

FIG. 11 is a diagram illustrating at least a portion of a non-display area according to an embodiment of the present disclosure;

FIG. 12 is a diagram illustrating at least a portion of a non-display area according to an embodiment of the present disclosure;

FIG. 13 is a diagram illustrating at least a portion of a non-display area according to another embodiment of the present disclosure;

FIG. 14 is a diagram illustrating at least a portion of a non-display area according to another embodiment of the present disclosure;

FIG. 15 is a diagram showing the first area of FIG. 13;

FIG. 16 is a diagram showing the second area of FIG. 13;

FIG. 17 is a diagram showing the third area of FIG. 14;

FIG. 18 is a block diagram of an electronic device according to an embodiment of the present disclosure;

FIG. 19 shows schematic diagrams of electronic devices according to various embodiments of the present disclosure;

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

In order to clearly explain the present invention, parts not related to the description are omitted, and the same or similar components are denoted by the same reference numerals throughout the specification. Accordingly, the aforementioned reference numerals may also be used in other drawings.

In addition, the size and thickness of each component shown in the drawings are arbitrarily shown for convenience of description, and therefore, the present invention is not necessarily limited to what is shown. Thicknesses may be exaggerated to clearly represent multiple layers and regions in the drawings.

Also, the expression “same” in the description may mean “substantially the same”. In other words, it may be the same enough that a person with ordinary knowledge can understand that they are the same. Other expressions may also be those in which “substantially” is omitted.

The terms first, second, or a, b, etc. may be used to describe various components, but the components should not be limited by the terms. The above terms are used only for the purpose of distinguishing one component from another. For example, a first component may be named a second component, and similarly, a second component may also be named a first component, without departing from the scope of the present invention.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless defined otherwise, all terms (including technical and scientific terms) used herein have the same meaning as commonly understood by one of ordinary skill in the art to which this invention belongs. In addition, terms such as those defined in commonly used dictionaries should be interpreted as having a meaning that is consistent with the meaning in the context of the relevant art, and are expressly defined herein unless interpreted in an ideal or overly formal sense.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments are described herein with reference to schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described in detail with reference to the accompanying drawings.

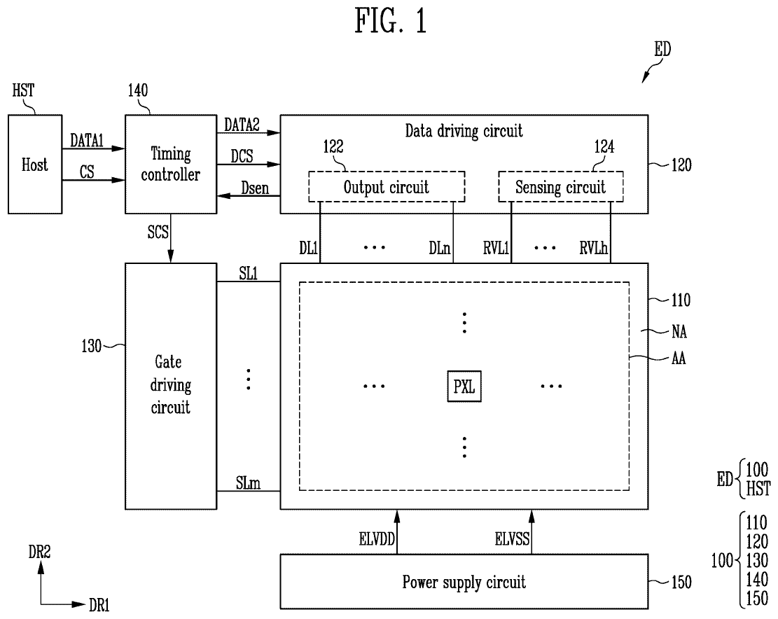

FIG. 1 is a block diagram of a display device 100 according to embodiments of the present disclosure.

Referring to FIG. 1, a display device 100 according to embodiments of the present disclosure may include a display panel 110, a data driving circuit 120, a gate driving circuit 130, a timing controller 140, a power supply circuit 150, and the like.

In an embodiment, a plurality of pixels PXL are disposed on the display panel 110. A plurality of data lines (DL1 to DLn; n is an integer of 2 or greater) electrically connected to a plurality of pixels PXL, a plurality of gate lines (SL1 to SLm; m is an integer of 2 or greater), a plurality of reference voltage lines (RVL1 to RVLh; h is an integer of 2 or greater), or the like may be disposed in the display panel 110. One or more power lines that apply a power supply voltage (for example, a first power supply voltage ELVDD, a second power supply voltage EPVSS, or the like) to the plurality of pixels PXL may be disposed on the display panel 110.

The display panel 110 may include a display area AA in which a plurality of pixels PXL are disposed, and a non-display area NA located in an area around the display area AA (e.g., an edge of the display area AA).

The display panel 110 may be formed flat, but is not limited thereto. In an embodiment, for example, the display panel 110 may include curved portions formed at left and right ends. A curved surface may have a constant curvature or a varying curvature. In addition, the display panel 110 may be flexibly formed to be bent, bent, bent, folded, or rolled.

The plurality of data lines DL1 to DLn may be disposed in the display panel 110 to extend in a second direction DR2 (for example, a direction from the upper side to the lower side of the display panel 110). The plurality of gate lines SL1 to SLm may be disposed to extend in a first direction DR1 (e.g., a direction from left to right of the display panel 110) different from the second direction DR2 in the display panel 110. The plurality of reference voltage lines RVL1 to RVLh may be arranged to extend in the second direction DR2 in the display panel 110, but is not limited thereto.

The data driving circuit 120 may include an output circuit 122 and a sensing circuit 124. According to an embodiment, the output circuit 122 and the sensing circuit 124 may be formed functionally separately in a same integrated circuit. According to an embodiment, the output circuit 122 and the sensing circuit 124 may be respectively formed in different integrated circuits.

The output circuit 122 is configured to supply a data voltage to the plurality of data lines DL1 to DLn. The output circuit 122 may generate a data voltage based on a second image data DATA2 and a data driving circuit control signal DCS, and output the generated data voltage to the plurality of data lines DL1 to DLn according to predetermined timings. The data driving circuit control signal DCS may include, for example, a source start pulse (SSP) signal, a source shift clock (SSC) signal, and a source output enable (SOE) signal.

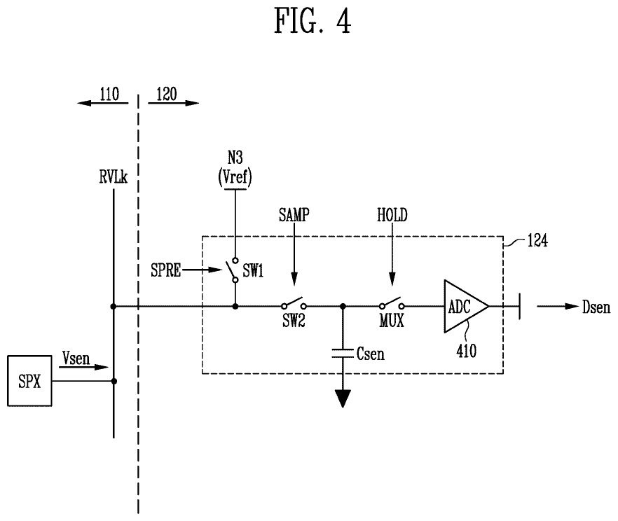

The sensing circuit 124 is configured to input a reference voltage to the plurality of reference voltage lines RVL1 to RVLh in response to the data driving circuit control signal DCS, and sense a voltage of the plurality of reference voltage lines RVL1 to RVLh. The sensing circuit 124 may convert the sensed voltage into a digital value Dsen corresponding thereto, and output the converted digital value Dsen. The sensing circuit 124 may include one or more analog digital converters (ADCs). The data driving circuit control signal DCS may include, for example, a reference voltage switching signal, a sampling control signal, a hold control signal, or the like. A detailed description of the above signals will be provided below with reference to FIG. 4.

The data driving circuit 120 may be implemented as an integrated circuit (e.g., a source driving integrated circuit (SDIC)) formed separately from the display panel 110, or may be formed together with the display panel 110 in at least a partial area on a non-display area NA of the display panel 110.

The gate driving circuit 130 is configured to output a gate signal (e.g., a scan signal, a sense signal) to the plurality of gate lines SL1 to SLm in response to the gate driving circuit control signal SCS. The gate driving circuit 130 may be implemented as a gate driving integrated circuit (GDIC) formed separately from the display panel 110, or may be formed together with the display panel 110 in at least a partial area on the non-display area NA of the display panel 110.

The timing controller 140 may be configured to control the data driving circuit 120 and the gate driving circuit 130. The timing controller 140 may generate and output control signals DCS and SCS for controlling the data driving circuit 120 and the gate driving circuit 130 based on a control signal CS (e.g., a synchronization signal, a clock signal, or the like) input through the outside (e.g., the host HST).

The timing controller 140 may receive a first image data DATA1 from an outside (for example, the host HST), and sort the input first image data DATA1 in units of pixel rows. The timing controller 140 may convert the input first image data DATA1 according to a preset interface (for example, a low voltage differential signaling (LVDS), an embedded display port (eDP), or the like). The second image data DATA2 output by the timing controller 140 to the data driving circuit 120 may be converted inside the timing controller 140 according to the preset interface.

The timing controller 140 may be arranged in the display device 100 in a logic or processor type. The timing controller 140 may include one or more registers.

The power supply circuit 150 is configured to output a constant voltage at a constant voltage level. The power supply circuit 150 may output, for example, the first power supply voltage ELVDD and the second power supply voltage ELVSS supplied to the display panel 110. The power supply circuit 150 may include, for example, a power management integrated circuit (PMIC).

The host HST may include at least one selected from a central processing unit (CPU), an application processor (AP), a graphics processing unit (GPU), a communication processor (CP), an image signal processor (ISP), and a controller. In an embodiment, the host HST may be provided in two or more segments from a functional or structural perspective. In an embodiment, for example, the host HST may include a main processor in the form of a first driving chip including a central processing unit, and an auxiliary processor in the form a second driving chip including a controller that receives an image signal from the main processor and processes the image signal to meet the interface specification of the display device 100. The host HST may output the first image data DATA1 and the control signal CS.

In FIG. 1, the driving circuits 120, 130, 140, and 150 that supply signals, voltages, and the like to the display panel 110 are merely classified according to functions for convenience of illustration and description. In an embodiment, for example, the data driving circuit 120 and the timing controller 140 may be formed in one integrated circuit. The data driving circuit 120 and the timing controller 140 may be classified according to functions in one integrated circuit.

The display device 100 according to embodiments of the present disclosure may be used as a display screen of various products such as a mobile phone, a smart phone, a tablet personal computer (PC), and a portable electronic device such as a smart watch, a watch phone, a mobile communication terminal, an electronic notebook, an electronic book, a portable multimedia player (PMP), navigation, an ultra-mobile personal computer (UMPC), and the like, as well as a television, a notebook, a monitor, an advertisement board, an Internet on Things (IoT) display device, and the like.

An electronic device ED according to embodiments of the present disclosure may include a host HST and a display device 100.

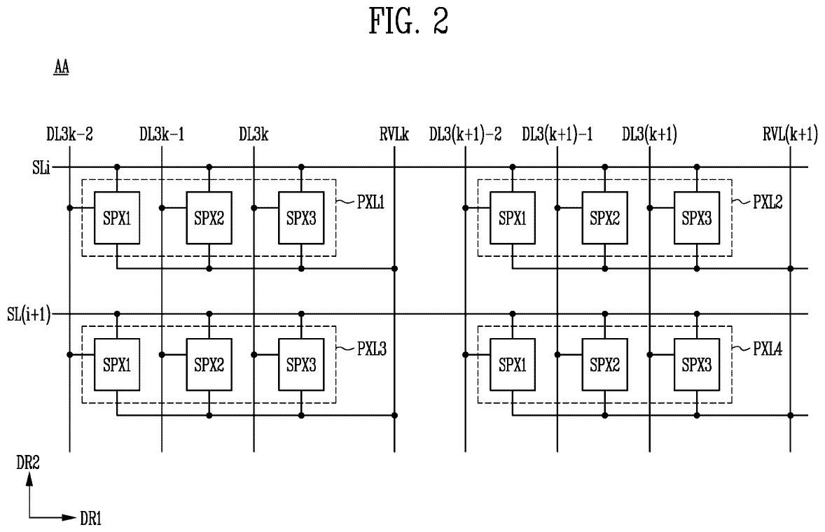

FIG. 2 is a block diagram of a display area AA according to embodiments of the present disclosure.

Referring to FIG. 2, four pixels PXL1, PXL2, PXL3, PXL4 (hereinafter PXL1 to PXL4) arranged in a matrix type are shown as an example. At least two of the four pixels PXL1 to PXL4 may be arranged adjacent to each other in a row direction (e.g., the first direction DR1), or may be arranged adjacent with each other in a column direction (e.g., the second direction DR2).

Any one of the four pixels PXL1 to PXL4 (e.g., the first pixel PXL1 located at the top left) may include three or more sub-pixels SP1, SP2, SP3.

The three sub-pixels SPX1, SPX2, and SPX3 constituting one pixel (for example, the first pixel PXL1) may be respectively configured to emit light of different wavelength bands. In an embodiment, for example, the first sub-pixel SPX1 may be configured to emit light in the red wavelength band. In an embodiment, for example, the second sub-pixel SPX2 may be configured to emit light in the green wavelength band. In an embodiment, for example, the third sub-pixel SPX3 may be configured to emit light in the blue wavelength band. According to an embodiment, one pixel (e.g., PXL1) may further include a white sub-pixel configured to emit white light. According to an embodiment, one pixel (e.g., PXL1) may include two or more sub-pixels (e.g., two or more second sub-pixels SPX2) configured to emit green light.

The red wavelength band may be a wavelength band from about 600 nm (nanometers) to about 750 nm. The green wavelength band may be a wavelength band of about 480 nm to about 560 nm. The blue wavelength band may be a wavelength band of about 370 nm to about 460 nm.

Hereinafter, embodiments where each of the four pixels PXL1 to PXL4 includes one first sub-pixel SPX1, one second sub-pixel SPX2, and one third sub-pixel SPX3 will be described as an example. However, embodiments of the present disclosure are not limited thereto.

In embodiments of the present disclosure, the sub-pixels SPX1, SPX2, and SPX3 constituting one pixel (for example, the first pixel PXL1) may be electrically connected to corresponding data lines, respectively. In an embodiment, for example, the first sub-pixel SPX1, the second sub-pixel SPX2, and the third sub-pixel SPX3 of the first pixel PXL1 (or the third pixel PXL3) may be electrically connected to three consecutive data lines DL3k−2, DL3k−1, and DL3k (k is an integer of 1 or greater), respectively. In an embodiment, for example, the first sub-pixel SPX1, the second sub-pixel SPX2, and the third sub-pixel SPX3 of the second pixel PXL2 (or the fourth pixel PXL4) may be electrically connected to three consecutive data lines DL3(k+1)−2, DL3(k+1)−1, and DL3(k+1), respectively.

In embodiments of the present disclosure, the sub-pixels SPX1, SPX2, and SPX3 constituting one pixel (for example, the first pixel PXL1) may be electrically connected to one reference voltage line. For example, the first sub-pixel SPX1, the second sub-pixel SPX2, and the third sub-pixel SPX3 of the first pixel PXL1 (or the third pixel PXL3) may be electrically connected to the k-th reference voltage line RVLk. In an embodiment, for example, the first sub-pixel SPX1, the second sub-pixel SPX2, and the third sub-pixel SPX3 of the second pixel PXL2 (or the fourth pixel PXL4) may be electrically connected to the (k+1)-th reference voltage line RVL(k+1). Although not illustrated, according to an embodiment, the sub-pixels SPX1, SPX2, and SPX3 constituting one pixel (for example, the first pixel PXL1) may be electrically connected to different reference voltage lines, respectively.

In embodiments of the present disclosure, the sub-pixels SPX1, SPX2, and SPX3 constituting one pixel (for example, the first pixel PXL1) may be electrically connected to one gate line. In an embodiment, for example, the first sub-pixel SPX1, the second sub-pixel SPX2, and the third sub-pixel SPX3 of the first pixel PXL1 (or the second pixel PXL2) may be electrically connected to the i-th gate line SLi (i is an integer greater than or equal to 1). In an embodiment, for example, the first sub-pixel SPX1, the second sub-pixel SPX2, and the third sub-pixel SPX3 of the third pixel PXL3 (or the fourth pixel PXL4) may be electrically connected to the (i+1)-th gate line SL(i+1).

Referring to FIG. 2, the first pixel PXL1 located at the top left and the second pixel PXL2 located at the top right are electrically connected to the same i-th gate line SLi. The first pixel PXL1 and the second pixel PXL2 are located in the same pixel row. Similarly, the third pixel PXL3 located at the lower left and the fourth pixel PXL4 located at the lower right are electrically connected to the same gate line SL (i+1). The third pixel PXL3 and the fourth pixel PXL4 are located in the same pixel row.

Referring to FIG. 2, the first pixel PXL1 located at the top left and the third pixel PXL3 located at the bottom left are electrically connected to same data lines DL3k−2, DL3k−1, and DL3k. The first pixel PXL1 and the third pixel PXL3 are located in a same pixel column. Similarly, the second pixel PXL2 located at the upper right and the fourth pixel PXL4 located at the lower right are electrically connected to same data lines DL3(k+1)−2, DL3(k+1)−1, DL3(k+1). The second pixel PXL2 and the fourth pixel PXL4 are located in a same pixel column.

In embodiments of the present disclosure, two or more pixel rows and two or more pixel columns may be located in the display area AA.

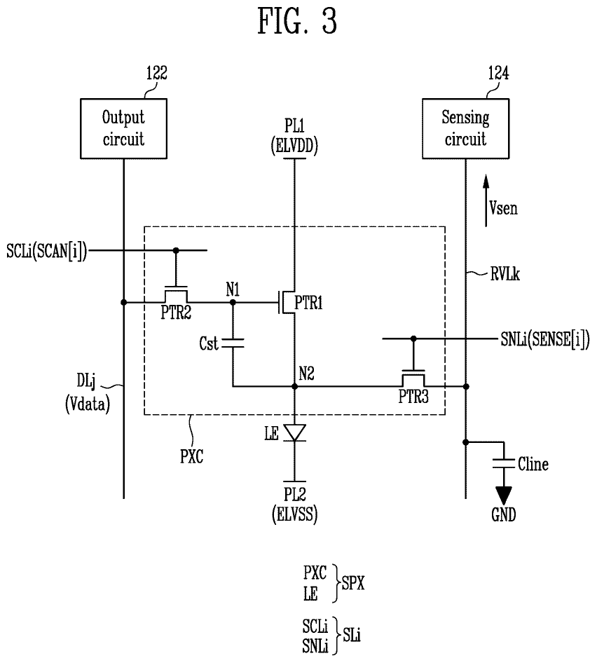

FIG. 3 is a circuit diagram illustrating an example of a sub-pixel SPX according to embodiments of the present disclosure.

The sub-pixel SPX according to embodiments of the present disclosure may include the light-emitting element LE and a pixel driving circuit PXC configured to supply a driving current to the light-emitting element LE. The pixel driving circuit PXC may include one or more transistors and one or more capacitors.

In an embodiment, for example, referring to FIG. 3, the pixel driving circuit PXC may include first to third pixel transistors PTR1 to PTR3 and a storage capacitor Cst.

The light-emitting element LE may include a first electrode (either an anode electrode and a cathode electrode), a second electrode (the other one of the anode electrode and the cathode electrode), and a light-emitting layer. The light-emitting element LE may include an organic light-emitting diode having an organic light-emitting layer. The light-emitting element LE may include an inorganic light-emitting diode including an inorganic light-emitting layer.

Referring to FIG. 3, a first electrode (e.g., an anode electrode) of the light-emitting element LE may be electrically connected to the second node N2. A second electrode (e.g., a cathode electrode) of the light-emitting element LE may be electrically connected to the second power line PL2.

The second power supply voltage ELVSS is applied to the second power line PL2. The second power supply voltage ELVSS may be, for example, a low potential power supply voltage or a ground voltage.

The first pixel transistor PTR1 may be connected (e.g., electrically connected) between the first power line PL1 and the second node N2. The first pixel transistor PTR1 may include a gate electrode, a first electrode (either a source electrode or a drain electrode), and a second electrode (the other of the source electrode and the drain electrode). The gate electrode of the first pixel transistor PTR1 may be electrically connected to the second pixel transistor PTR2 at the first node N1. The first electrode (e.g., a drain electrode) of the first pixel transistor PTR1 may be electrically connected to the first power line PL1. The first power supply voltage ELVDD may be applied to the first electrode of the first pixel transistor PTR1. The first power supply voltage ELVDD may be, for example, a high potential power supply voltage. The second electrode (for example, a source electrode) of the first pixel transistor PTR1 may be electrically connected to the light-emitting element LE at the second node N2. The first pixel transistor PTR1 may receive a data voltage Vdata through the second pixel transistor PTR2. A current (for example, a drain current or a driving current) having a magnitude corresponding to the input data voltage Vdata may flow through the first pixel transistor PTR1.

The second pixel transistor PTR2 may be configured or connected to switch an electrical connection between the data line DLj and the first node N1. The operation timing of the second pixel transistor PTR2 can be controlled by the i-th scan signal SCAN[i]. The second pixel transistor PTR2 is turned on in response to the i-th scan signal SCAN[i] at the turn-on level, and a data voltage Vdata (or a voltage corresponding to the data voltage Vdata) may be applied to the first node N1.

The third pixel transistor PTR3 may be configured or connected to switch an electrical connection between the second node N2 and the reference voltage line RVLk. The operation timing of the third pixel transistor PTR3 may be controlled by the sense signal SENSE[i]. The third pixel transistor PTR3 may be turned on in response to the sense signal SENSE[i] at the turn-on level. When the third pixel transistor PTR3 is turned on, the voltage of the second node N2 may be applied to the reference voltage line RVLk. The voltage applied to the reference voltage line RVLk may be stored in a line capacitor Cline.

Referring to FIG. 3, in an embodiment, the first to third pixel transistors PTR1 to PTR3 may be N-type transistors. In such an embodiment, the first to third pixel transistors PTR1 to PTR3 may have a turn-on level voltage of a high level voltage and a turn-off level voltage of a low level voltage. According to an embodiment, at least one of the first to third pixel transistors PTR1 to PTR3 may be a P-type transistor. In such an embodiment, the turn-on level voltage of the P-type transistor may be a low level voltage, and the turn-off level voltage may be a high level voltage.

At least one of the first to third pixel transistors PTR1 to PTR3 may include an amorphous silicon (a-Si) semiconductor. At least one of the first to third pixel transistors PTR1 to PTR3 may include a polycrystalline silicon (poly-Si) semiconductor. At least one of the first to third pixel transistors PTR1 to PTR3 may include an oxide semiconductor.

The storage capacitor Cst may be configured to maintain a voltage difference between the first node N1 and the second node N2. The storage capacitor Cst may include one electrode electrically connected to first node N1 and the other electrode electrically connected to second node N2. The storage capacitor Cst may be formed of a physical capacitor element rather than a parasitic capacitor.

The i-th scan signal SCAN[i] may be applied to the i-th scan line SCLi (or an i-th first gate line SCLi). The sense signal SENSE[i] may be applied to the i-th sense line SNL[i] (or an i-th second gate line SNLi). The i-th scan signal SCAN[i] and the sense signal SENSE[i] may be different signals. In this embodiment, the i-th scan line SCLi and the i-th sense line SNLi may be different lines. Referring to FIG. 1 together with FIG. 3, the i-th gate line SLi may include the i-th scan line SCLi and the i-th sense line SNLi.

The output circuit 122 may output the data voltage Vdata to the j-th data line DLj. The sensing circuit 124 may receive the analog sensing voltage Vsen applied to the k-th reference voltage line RVLk. The analog sensing voltage Vsen may be a voltage in which a characteristic value of the first pixel transistor PTR1 (for example, a threshold voltage of the first pixel Transistor PTR1) is reflected.

FIG. 4 is a diagram illustrating a sensing circuit 124 in embodiments of the present disclosure.

In an embodiment, the sensing circuit 124 may be included in the data driving circuit 120. The sensing circuit 124 may receive the analog sensing voltage Vsen from the k-th reference voltage line RVLk. The sensing circuit 124 may convert the input analog sensing voltage Vsen into a digital value Dsen and output the digital value Dsen.

Referring to FIG. 4, the sensing circuit 124 may include a first switching element SW1, a second switching element SW2, a multiplexer MUX, a sensing capacitor Csen, an analog-to-digital converter (ADC) 410, or the like.

The first switching element SW1 may be configured for switching an electrical connection between the third node N3 and the k-th reference voltage line RVLk. The operation timing of the first switching element SW1 may be controlled by the reference voltage switching signal SPRE. When the first switching element SW1 is turned on in response to the reference voltage switching signal SPRE of the turn-on level, the reference voltage Vref may be applied to the k-th reference voltage line RVLk. The first switching element SW1 may include or be defined by, for example, a transistor.

The second switching element SW2 may be configured for switching the electrical connection between the k-th reference voltage line RVRk and the sensing capacitor Csen. The operating timing of the second switching element SW2 may be controlled by the sampling control signal SAMP. When the second switching element SW2 is turned on by the sampling control signal SAMP at the turn-on level, the analog sensing voltage Vsen is applied to the sensing capacitor Csen. The second switching element SW2 may comprise, for example, a transistor.

The sensing capacitor Csen may include one electrode connected (e.g., electrically connected) to the second switching element SW2 and the other electrode to which a constant voltage (or ground) is applied. A voltage corresponding to the analog sensing voltage Vsen may be stored in one electrode of the sensing capacitor Csen.

The multiplexer MUX may be configured or connected to switch an electrical connection between the sensing capacitor Csen and the analog-to-digital converter 410. The multiplexer MUX may include two or more input terminals. An input end of the multiplexer MUX may be connected (e.g., electrically connected) to one electrode of the sensing capacitor Csen. The operation timing of the multiplexer MUX may be controlled by a hold control signal HOLD. When the multiplexer MUX is turned on by the hold control signal HOLD at the turn-on level, a voltage stored in the sensing capacitor Csen (for example, the analog sensing voltage Vsen) may be input to the analog-to-digital converter 410.

The analog-to-digital converter 410 may be configured to convert an analog voltage into a digital voltage and output the digital voltage. The analog-to-digital converter 410 may receive an analog voltage (e.g., an analog sensing voltage Vsen) and output a digital value Dsen corresponding to the input analog voltage.

Accordingly, in embodiments of the present disclosure, the sensing circuit 124 may convert the analog sensing voltage Vsen sensed by the sub-pixel SPX into a digital value Dsen corresponding thereto and output the digital value Dsen.

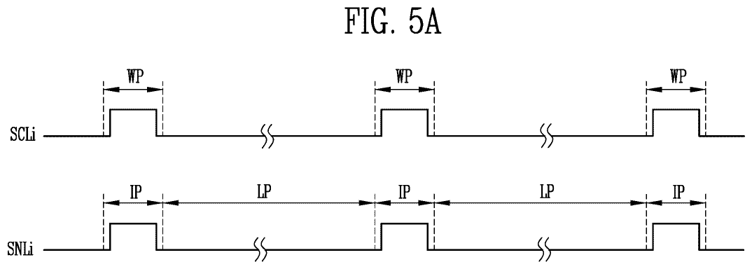

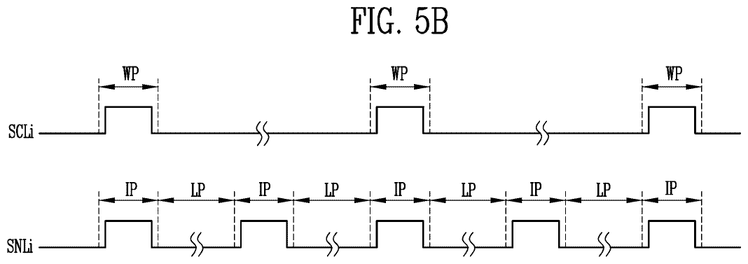

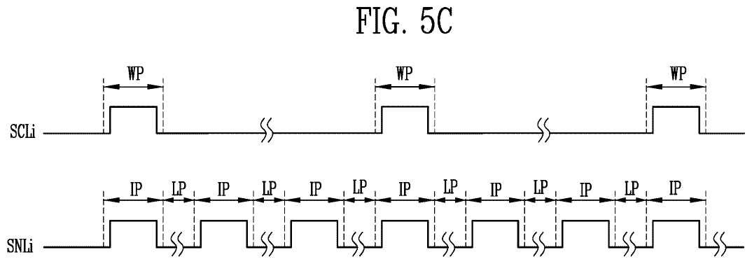

FIGS. 5A, 5B, and 5C are signal diagrams illustrating examples of a driving method in which the display device 100 of FIG. 1 displays images at different frame rates.

Referring to FIG. 5A, a period during which the turn-on level voltage is applied to the i-th scan line SCLi may correspond to a data writing period (or also referred to as a writing period) WP. When the frame is started (or switched), a data voltage (Vdata; see FIG. 3) may be input (or written or applied) to the sub-pixel. In the data writing period WP, a data voltage for displaying an image of a corresponding frame may be input to the sub-pixel. The sub-pixel may store (e.g., store in a storage capacitor) the input data voltage and emit light for at least a portion of a period of the frame based on the stored data voltage.

The period in which the turn-on level voltage is applied to the sense line SNLi may correspond to the initialization period IP. When the frame is started, a reference voltage Vref (see FIG. 3) may be input to the sub-pixel. In the initialization period IP, a reference voltage is input to the sub-pixel, and the light-emitting element LE (see FIG. 3) of the sub-pixel does not emit light.

The period in which the turn-off level voltage is applied to the sense line SNLi may include a light emission period LP. The sub-pixel may emit light in the light emission period LP based on the data voltage input in the data writing period WP.

Referring to FIG. 5A, the data writing period WP and the initialization period IP may overlap at least in part. In an embodiment, for example, the data writing period WP and the initialization period IP may coincide with each other. However, embodiments of the present disclosure are not limited thereto. In an embodiment, for example, the data write period WP and the initialization period IP may not (temporally) overlap each other.

According to an embodiment, when a refresh frame rate (a frequency at which a frame is switched, or a period at which a data voltage is input to a sub-pixel) is reduced, a ratio occupied by an initialization period IP within one frame period may also be reduced. In other words, the length of the non-emission period during which the light-emitting element does not emit light within one frame period may be relatively small. In this case, it may be perceived by the user that the luminance increases as the refresh frame rate decreases, or that the luminance decreases as the refresh frame rates increase. Such an increase or decrease in luminance may be perceived by the user as a blinking phenomenon (also referred to as a flicker phenomenon).

Referring to FIG. 5B and FIG. 5C, in embodiments of the present disclosure, the display device 100 may apply the voltage of the turn-on level (or the sense signal of the turn-off level) to the i-th sense line SNLi in at least a part of a period of time during which the voltage of the turn-off level (or the scan signal of the turn-on level) is applied to the i-th scan line SCLi to mitigate the blinking phenomenon. Accordingly, the light-emitting element of the sub-pixel may blink within one frame period. The display device 100 (see FIG. 1) according to embodiments of the present disclosure may control (e.g., control the light-emitting element according to a preset period so that the driving current does not flow) the light-emitting element when the refresh frame rate decreases. Accordingly, it is possible to alleviate the phenomenon in which a sudden change in luminance is recognized as the refresh frame rate changes. The visibility may thereby be improved.

Referring to FIG. 5B, the initialization period IP may be performed once in a period that does not overlap the data writing period WP in one frame period. Referring to FIG. 5C, the initialization period IP may be performed two or more times in a period that does not overlap the data writing period WP in one frame period.

Referring to FIGS. 5A to 5C, the refresh frame rate shown in FIG. 5A may be, for example, 240 Hz (Hertz). The refresh frame rate shown in FIG. 5B may be, for example, 80 Hz to 120 Hz. The refresh frame rate of FIG. 5C may be, for example, 60 Hz to 80 Hz. Embodiments of the present disclosure are not limited as described above, and the presented refresh frame rate is merely an example.

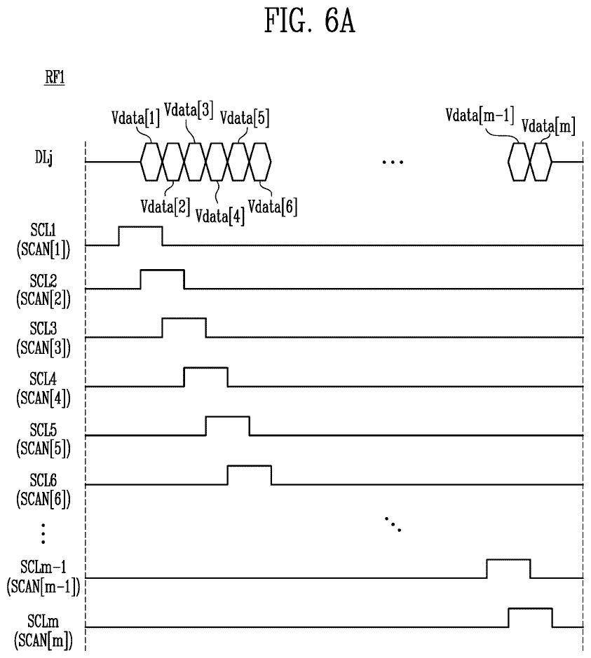

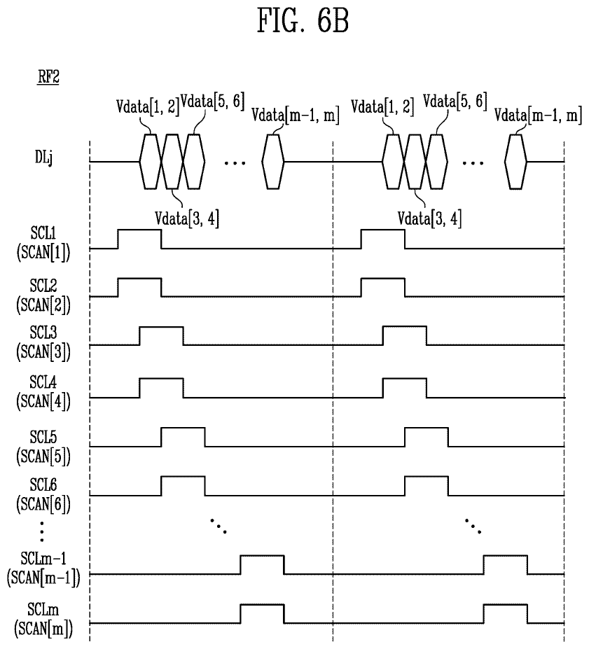

FIG. 6A is a signal timing diagram illustrating an example of the first refresh frame rate RF1. FIG. 6B is a signal timing diagram illustrating an example of the second refresh frame rate RF2.

Referring to FIG. 6A, scan signals (e.g., scan signals at the turn-on level) may be sequentially output to the first refresh frame rate RF1 through the first to m-th scan lines SCL1 to SCLm. In an embodiment, for example, the first scan signal SCAN[1], the second scan signal SCAN[2], the third scan signal SCAN[3], the fourth scan signal SCAN[4], the fifth scan signal SCAN[5], and the sixth scan signal SCAN[6] of the turn-on level may be sequentially output. Subsequently, the (m−1)-th scan signal SCAN[m−1] and the m-th scan signal SCAN[m] at the turn-on level may be output sequentially. Within one frame period, the first scan signal SCAN[1] to the m-th scan signal SCAN[m] may be output.

The first scan signal SCAN[1] may be output to write the data voltage Vdata[1] to the corresponding sub-pixel. The second scan signal SCAN[2] may be output to write the corresponding data voltage Vdata[2] to the corresponding sub-pixel. Likewise, the third to m-th scan signals SCAN[3] to SCAN[m] may also be output to write data voltages Vdata[3] to Vdata[m] to the corresponding sub-pixel.

The first scan signal SCAN[1] may overlap the second scan signal SCAN[2] with at least part of the period having the turn-on level, and may not overlap the third to m-th scan signals SCAN[3] to SCAN[m] with the period having the turn-on level. The second scan signal SCAN[2] may overlap at least part of the period with the turn-on level with the first scan signal SCAN[1] and the third scan signal SCAN[3], and may not overlap the period with the fourth to m-th scan signals SCAN[4] to SCAN[m].

In an embodiment, as shown in FIG. 6A, different data voltages corresponding thereto may be applied to the sub-pixels connected to the first to m-th scan lines SCL1 to SCLm, respectively.

In an embodiment, this first refresh frame rate RF1 may be the same as the refresh frame rate described above with reference to FIG. 5A. In an embodiment, for example, the first refresh frame rate RF1 may be about 240 Hz, but embodiments of the present disclosure are not limited thereto.

In an embodiment in which the first refresh frame rate RF1 is the same as the refresh frame rate described with reference to FIG. 5A described above, the plurality of sense lines (for example, including the i-th sense line SNLi described through FIG. 3) may be driven similarly to the plurality of scan lines SCL1 to SCLm described through FIG. 6A.

Referring to FIG. 6A, a high resolution image may be displayed at a first refresh frame rate RF1 according to embodiments of the present disclosure.

Referring to FIG. 6B, at least some of the scan signals (e.g., scan signals at the turn-on level) may be simultaneously output via the first through m-th scan lines SCL1 through SCLm at the second refresh frame rate RF2. In an embodiment, for example, the first scan signal SCAN[1] and the second scan signal SCAN[2] at the turn-on level may be output simultaneously. The third scan signal SCAN[3] and the fourth scan signal SCAN[4] of the turn-on level may be output simultaneously. The fifth scan signal SCAN[5] and the sixth scan signal SCAN [6] of the turn-on level may be output simultaneously. Then sequentially, the (m−1)-th scan signal SCAN[m−1] and the m-th scan signal SCAN[m] at the turn-on level may be output simultaneously. Within one frame period, at least two of the first scan signal SCAN[1] to the m-th scan signal SCAN[m] may be sequentially output in pairs.

The first scan signal SCAN[1] may be output to write the data voltage Vdata[1, 2] to the corresponding sub-pixel. The second scan signal SCAN[2] may be output to write the data voltage Vdata[1, 2] to the corresponding sub-pixel. The third scan signal SCAN[3] may be output to write the data voltage Vdata[3, 4] to the corresponding sub-pixel. The fourth scan signal SCAN[4] may be output to write the data voltage Vdata[3, 4] to the corresponding sub-pixel. The fifth scan signal SCAN[5] may be output to write the data voltage Vdata[5, 6] to the corresponding sub-pixel. The sixth scan signal SCAN[6] may be output to write the data voltage Vdata[5, 6] to the corresponding sub-pixel. Likewise, the (m−1)-th scan signal SCAN[m−1] may be output to write the data voltage Vdata[m−1, m] to its corresponding sub-pixel. The m-th scan signal SCAN[m] may be output to write the data voltage Vdata[m−1, m] to the corresponding sub-pixel.

Here, the first scan signal SCAN[1] is the same as the second scan signal SCAN[2], and at least a part of the period having the turn-on level may overlap the third scan signal SCAN[3] and the fourth scan signal SCAN[4]. On the other hand, the period having the turn-on level may not overlap the fifth scan signal SCAN[5] and the sixth scan signal SCAN [6]. Likewise, the second scan signal SCAN[2] is identical to the first scan signal SCAN[1], and at least part of the time period with the turn-on level may overlap with the third scan signal SCAN [3] and the fourth scan signal SCAN[4]. On the other hand, the period having the turn-on level may not overlap the fifth scan signal SCAN[5] and the sixth scan signal SCAN [6].

In an embodiment, as shown in FIG. 6B, the same data voltage may be applied to at least two of the sub-pixels connected with the first to m-th scan lines SCL1 to SCLm.

In an embodiment, the second refresh frame rate RF2 may be about twice the first refresh frame rate RF1. In an embodiment, for example, the second refresh frame rate RF2 may be about 480 Hz, but embodiments of the present disclosure are not limited thereto.

In an embodiment in which the second refresh frame rate RF2 is about twice the first refresh frame rate RF1 described with reference to FIG. 6A, the plurality of sense lines (for example, including the i-th sense line SNLi described through FIG. 3) may be driven similarly to the plurality of scan lines SCL1 to SCLm described through FIG. 6B.

Referring to FIG. 6B, according to embodiments of the present disclosure, an image having a half resolution compared to the embodiment of FIG. 6A may be displayed at a second refresh frame rate RF2 that is more than twice as fast as the embodiment of FIG. 6A.

Referring to FIGS. 5A to 6B as a whole, a display device 100 (see FIG. 1) according to embodiments of the present disclosure may display an image at a wide variety of refresh frame rates.

In an embodiment, for example, based on the refresh frame rate of about 240 Hz described with reference to FIGS. 5A and 6A, an image with a refresh frame rate lower than the refresh frame rate may be displayed through the driving method described with reference to FIG. 5B and FIG. 5C. In addition, an image with a higher refresh frame rate can be displayed through the driving method described in FIG. 6B.

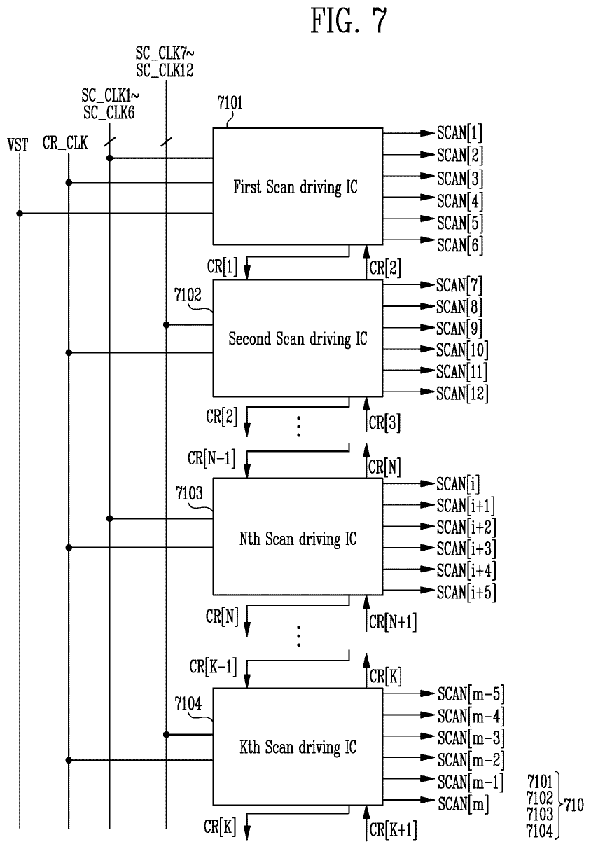

FIG. 7 is a block diagram of an embodiment of a scan driving circuit 710.

In an embodiment, the scan driving circuit 710 may include a plurality of scan driving integrated circuits. Although four scan driving integrated circuits 7101 to 7104 of the scan driving circuit 710 are shown in FIG. 7 for ease of illustration and description, embodiments of the present disclosure are not limited thereto.

Each of the scan driving integrated circuits 7101 to 7104 corresponds to a stage of the scan driving circuit 710. An embodiment in which each of the scan driving integrated circuits 7101 to 7104 outputs two or more scan signals, for example, six scan signals, is shown in FIG. 7. However, embodiments of the present disclosure are not so limited, and each of the scan driving integrated circuits 7101 to 7104 may be configured to output more than six scan signals.

At least one of the scan driving integrated circuits 7101 to 7104 may receive at least six of the twelve scan clock signals SC_CLK1 to SC_CLK12. At least one of the scan driving integrated circuits 7101 to 7104 may receive a carry clock signal CR_CLK. At least one of the scan driving integrated circuits 7101 to 7104 may receive a start signal VST or a carry signal from a preceding scan driving integrated circuit. At least one of the scan driving integrated circuits 7101 to 7104 may receive a carry signal from a subsequent scan driving integrated circuit.

The scan driving circuit 710 may include a first scan driving integrated circuit 7101, a second scan driving integrated circuit 7102, an N-th scan driving integrated circuit (N is an integer greater than 2) 7103, and a K-th scan driving integrated circuit (K is an integer greater than N) 7104.

The first scan driving integrated circuit 7101 may receive the first to sixth scan clock signals SC_CLK1 to SC_CLK6 among the twelve scan clock signals SC_1 to SC_CLK12. The first scan driving integrated circuit 7101 may receive a carry clock signal CR_CLK. The first scan driving integrated circuit 7101 may receive a start signal VST. The first scan driving integrated circuit 7101 may receive a carry signal CR[2] from a subsequent second scan driving integrated circuit 7102.

The first scan driving integrated circuit 7101 may output first through sixth scan signals SCAN[1] through SCAN[6]. The first scan driving integrated circuit 7101 may output the carry signal CR[1].

The second scan driving integrated circuit 7102 may receive the seventh to twelfth scan clock signals SC_CLK7 to SC_CLK12 from among the twelve scan clock signals SC_1 to SC_CLK 12. The second scan driving integrated circuit 7102 may receive the carry clock signal CR_CLK. The second scan driving integrated circuit 7102 may receive the carry signal CR[1] from the preceding first scan driving integrated circuit 7101. The second scan driving integrated circuit 7102 may receive the carry signal CR[3] from the following third scan driving integrated circuit.

The second scan driving integrated circuit 7102 may output the seventh to twelfth scan signals SCAN[7] to SCAN[12]. The second scan driving integrated circuit 7102 may output a carry signal CR[2].

The N-th scan driving integrated circuit 7103 may receive the first to sixth scan clock signals SC_CLK1 to SC_CLK6 among the twelve scan clock signals SC_1 to SC_CLK12. The N-th scan driving integrated circuit 7103 may receive the carry clock signal CR_CLK. The N-th scan driving integrated circuit 7103 may receive the carry signal CR[N−1] from the preceding N-th scan driving integrated circuit. The N-th scan driving integrated circuit 7103 may receive the carry signal CR[N+1] from the following (N+1)-th scan driving integrated circuit.

The N-th scan driving integrated circuit 7103 may output the i-th to (i+5)-th scan signals SCAN[i] to SCAN[i+5]. The N-th scan driving integrated circuit 7103 may output the carry signal CR[N].

The K-th scan driving integrated circuit 7104 may receive the seventh to twelfth scan clock signals SC_CLK7 to SC_CLK12 among the twelve scan clock signals SC_1 to SC_CLK 12. The K-th scan driving integrated circuit 7104 may receive the carry clock signal CR_CLK. The K-th scan driving integrated circuit 7104 may receive the carry signal CR[K−1] from the preceding (K−1)-th scan driving integrated circuit. The K-th scan driving integrated circuit 7104 may receive the carry signal CR[K+1] from the following (K+1)-th scan driving integrated circuit.

The K-th scan driving integrated circuit 7104 may output (m−5)-th to m-th scan signals SCAN[m−5] to SCAN[m]. The K-th scan driving integrated circuit 7104 may output the carry signal CR[k].

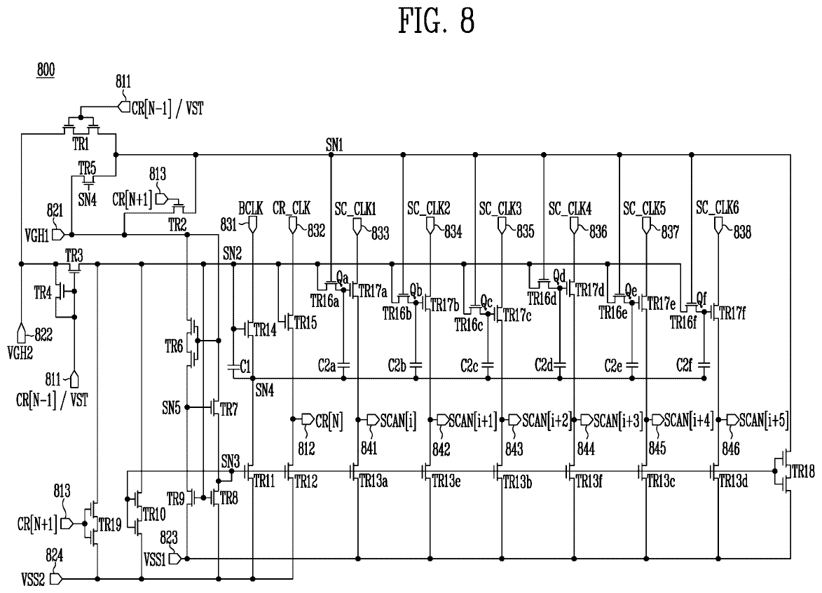

In FIG. 8 below, the N-th scan driving integrated circuit 7103 is shown as an example, and its configuration and driving method will be described in greater detail with reference to FIG. 8. The configuration of the N-th scan driving integrated circuit 7103 and its method of driving may be similarly applied to other scan driving integrated circuits included in the scan driving circuit 710.

FIG. 8 is an equivalent circuit diagram of a scan driving integrated circuit 800, according to an embodiment.

Referring to FIG. 8, a scan driving integrated circuit 800 according to embodiments of the present disclosure may include one or more terminals, one or more transistors, and one or more capacitors. The configuration of the scan driving integrated circuit 800 according to an embodiment will hereinafter be described in detail.

In an embodiment of the scan driving integrated circuit 800, a first transistor TR1 may be configured or connected to switch an electrical connection between the second power supply terminal 822 and the first node SN1 in response to a signal input to the first carry terminal 811. A start signal VST or a carry signal CR[N−1] of a previous stage may be input to the first carry terminal 811. A second high voltage VGH2 may be applied to the second power supply terminal 822. The second high voltage VGH2 may be a turn-on level voltage of the sixteenth transistors T16a to T16f. In an embodiment, the first transistor TR1 may have a double gate structure in which two transistors are connected in series with each other while sharing a gate electrode. However, embodiments of the present disclosure are not limited thereto, and the first transistor TR1 may be implemented as one transistor.

In an embodiment of the scan driving integrated circuit 800, a second transistor TR2 may be configured or connected to switch an electrical connection between the first power supply terminal 821 and the first node SN1 in response to a signal input to the third carry terminal 813. The carry signal CR[N+1] of the following stage may be input to the third carry terminal 813. A first high voltage VGH1 may be applied to the first power supply terminal 821. The voltage level of the first high voltage VGH1 may be lower than the voltage level of the second power supply voltage VGH2. In an embodiment, for example, the first high voltage VGH1 may be a turn-off level voltage of sixteenth transistors T16a to T16f. The voltage level of the first high voltage VGH1 may be higher than that of the first low voltage VSS1.

In an embodiment of the scan driving integrated circuit 800, a third transistor TR3 may be configured or connected to switch an electrical connection between the second power supply terminal 822 and the second node SN2 in response to a signal input to the first carry terminal 811.

In an embodiment of the scan driving integrated circuit 800, a fourth transistor TR4 may include a gate electrode connected to the first carry terminal 811. The fourth transistor TR4 may be configured or connected to switch an electrical connection between the third transistor TR3 and the first carry terminal 811. When the start signal VST or the carry signal CR[N−1] of the previous stage is input, the third transistor TR3 and the fourth transistor TR4 may be turned on together. Thereby, the second power supply voltage VGH2 is applied to the second node SN2, so that the eighth transistor TR8, the ninth transistor TR9, the fourteenth transistor TR14, and the fifteenth transistor TR15 may be turned on.

The first to fourth transistors TR1 to TR4 may constitute a pre-charge unit (or a pre-charge circuit).

In an embodiment of the scan driving integrated circuit 800, a fifth transistor TR5 may be configured or connected to switch an electrical connection between the first power supply terminal 821 and the first node SN1 in response to a voltage applied to the fourth node SN4. When the fifth transistor TR5 is turned on, a current path may be formed at the first node SN1 in the direction of the first power supply terminal 821 through the fifth transistor TR5. The voltage of the first node SN1 may thereby be discharged.

In an embodiment of the scan driving integrated circuit 800, a sixth transistor TR6 may be configured or connected to switch an electrical connection between the first power supply terminal 821 and the fifth node SN5 in response to a voltage input to the first power supply terminal 821. The first high voltage VGH1 input to the first power supply terminal 821 may be a turn-on level voltage of the sixth transistor TR6. In an embodiment, the sixth transistor TR6 may have a double gate structure in which two transistors are connected in series with each other while sharing a gate electrode. However, embodiments of the present disclosure are not limited thereto, and the sixth transistor TR6 may be implemented as one transistor.

In an embodiment of the scan driving integrated circuit 800, a seventh transistor TR7 may be configured or connected to switch an electrical connection between the first power supply terminal 821 and the third node SN3 in response to a voltage applied to the fifth node SN5. When the seventh transistor TR7 is turned on, a voltage corresponding to the first high voltage VGH1 is applied to the third node SN3, such that the eleventh transistor TR11, the twelfth transistor TR12, the thirteenth transistors TR13a to TR13f, and the eighteenth transistor TR18 may be turned on.

In an embodiment of the scan driving integrated circuit 800, an eighth transistor TR8 may be configured or connected to switch an electrical connection between the fourth power supply terminal 824 and the third node SN3 in response to a voltage applied to the second node SN2. A second low voltage VSS2 may be applied to the fourth power supply terminal 824. When the eighth transistor TR8 is turned on, the second low voltage VSS2 is applied to the third node SN3, so that the tenth transistor TR10, the eleventh transistor TR11, the twelfth transistor TR12, the thirteenth transistors TR13a to TR13f, and the eighteenth transistor TR18 may be turned off.

In an embodiment of the scan driving integrated circuit 800, a ninth transistor TR9 may be configured or connected to switch an electrical connection between the third power supply terminal 823 and the fifth node SN5 in response to a voltage applied to the second node SN2. The first low voltage VSS1 may be applied to the third power supply terminal 823. The eighth transistor TR8 and the ninth transistor TR9 may be turned on together in response to the voltage of the second node SN2. When the ninth transistor TR9 is turned on, the first low voltage VSS1 is applied to the fifth node SN5, so that the seventh transistor TR7 may be turned off. Thereby, the first power supply terminal 821 and the third node SN3 can be electrically insulated.

In an embodiment of the scan driving integrated circuit 800, a tenth transistor TR10 may be configured or connected to switch an electrical connection between the second node SN2 and the fourth power supply terminal 824 in response to a voltage applied to the third node SN3. When the tenth transistor TR10 is turned on, the second low voltage VSS2 may be applied to the second node SN2. The second low voltage VSS2 may be applied to one electrode of a first capacitor C1 electrically connected to the second node SN2. Thereby, the voltage of the second node SN2 may be discharged. The tenth transistor TR10 may have a double gate structure in which two transistors are connected in series with each other while sharing a gate electrode. However, embodiments of the present disclosure are not limited thereto, and the tenth transistor TR10 may be implemented as one transistor.

The sixth to tenth transistors TR6 to TR10 may constitute an inverter having the second node SN2 as an input node and the third node SN3 as an output node.

In an embodiment of the scan driving integrated circuit 800, an eleventh transistor TR11 may be configured or connected to switch an electrical connection between the fourth node SN4 and the fourth power supply terminal 824 in response to a voltage of the third node SN3. When the eleventh transistor TR11 is turned on, a current path from the fourth node SN4 to the fourth power supply terminal 824 via the eleventh transistor TR11 may be formed. Thereby, the voltage of the fourth node SN4 may be discharged.

In an embodiment of the scan driving integrated circuit 800, a twelfth transistor TR12 may be configured or connected to switch an electrical connection between the second carry terminal 812 and the fourth power supply terminal 824 in response to a voltage of the third node SN3. The carry signal CR[N] of the current stage may be output to the second carry terminal 812. When the twelfth transistor TR12 is turned on, the second low voltage VSS2 may be output through the second carry terminal 812.

In an embodiment of the scan driving integrated circuit 800, the thirteenth transistors TR13a to TR13f may be configured or connected to switch the electrical connection between the scan output terminals 841 to 846 and the third power supply terminal 823 in response to the voltage of the third node SN3. In an embodiment, the thirteenth transistors TR13a to TR13f are composed of or include six transistors, which may include an a-th thirteenth transistor TR13a, a b-th thirteenth transistor TR13b, a c-th thirteenth transistor TR13c, a d-th thirteenth transistor TR13d, an e-th thirteenth transistor TR13e, and an f-th thirteenth transistor TR13f. However, embodiments of the present disclosure are not limited thereto, and the thirteenth transistors TR13a to TR13f may be implemented to include more than six transistors, or to include fewer than six transistors.

The a-th thirteenth transistor TR13a may be configured or connected to switch an electrical connection between the first scan output terminal 841, which outputs the i-th scan signal SCAN[i], and the third power supply terminal 823.

The b-th thirteenth transistor TR13b may be configured or connected to switch an electrical connection between the second scan output terminal 842, which outputs the (i+1)-th scan signal SCAN[i+1], and the third power supply terminal 823.

The c-th thirteenth transistor TR13c may be configured or connected to switch an electrical connection between the third scan output terminal 843, which outputs the (i+2)-th scan signal SCAN[i+2], and the third power supply terminal 823.

The d-th thirteenth transistor TR13d may be configured or connected to switch an electrical connection between the fourth scan output terminal 844, which outputs the (i+3)-th scan signal SCAN[i+3], and the third power supply terminal 823.

The e-th thirteenth transistor TR13e may be configured or connected to switch an electrical connection between the fifth scan output terminal 845, which outputs the (i+4)-th scan signal SCAN[i+4], and the third power supply terminal 823.

The f-th thirteenth transistor TR13f may be configured or connected to switch the electrical connection between the sixth scan output terminal 846, which outputs the (i+5)-th scan signal SCAN[i+5], and the third power supply terminal 823.

When the thirteenth transistors TR13a to TR13f are turned on, the first low voltage VSS1 may be output through the scan output terminals 841 to 846.

The eleventh transistor TR11, the twelfth transistor TR12, and the thirteenth transistors TR13a to TR13f may constitute a pull-down unit (or a pull-down circuit).

In an embodiment of the scan driving integrated circuit 800, a fourteenth transistor TR14 may be configured or connected to switch an electrical connection between the first clock terminal 831 and the fourth node SN4 in response to a voltage applied to the second node SN2. A boosting clock signal BCLK may be applied to the first clock terminal 831. When the fourteenth transistor TR14 is turned on, the first clock terminal 831 may be electrically connected to the fourth node SN4 via the fourteenth diode TR14. When the boosting clock signal BCLK is applied to the fourth node SN4, the voltage of the second node SN2 may increase (or be boosted) by the coupling effect of the first capacitor C1.

In an embodiment of the scan driving integrated circuit 800, a first capacitor C1 may include one electrode connected to the second node SN2 and the other electrode connected to the fourth node SN4. The first capacitor C1 may be configured to maintain a voltage difference between the second node SN2 and the fourth node SN4. The first capacitor C1 may be pre-charged by the second high voltage VGH2. When the voltage of the fourth node SN4 rises due to the boosting clock signal BCLK, the voltage of the second node SN2 may rise due to the coupling effect of the first capacitor C1.

The fourteenth transistor TR14 and the first capacitor C1 may constitute a boosting unit (or a boosting circuit).

In an embodiment of the scan driving integrated circuit 800, a fifteenth transistor TR15 may be configured or connected to switch an electrical connection between the second clock terminal 832 and the second carry terminal 812 in response to a voltage of the second node SN2. The carry clock signal CR_CLK may be input to the second clock terminal 832. When the fifteenth transistor TR15 is turned on, the carry clock signal CR_CLK may be output as the carry signal CR[N] of the current stage through the second carry terminal 812. The fifteenth transistor TR15 may function as an output buffer for outputting the carry signal CR[N] of the current stage.

In an embodiment of the scan driving integrated circuit 800, a sixteenth transistors TR16a to TR16f may be configured or connected to switch an electrical connection between second capacitors C2a to C2f and the second node SN2 in response to the voltage of the first node SN1. In an embodiment, the sixteenth transistors TR16a to TR16f are composed of or includes six transistors, which may include an a-th sixteenth transistor TR16a, a b-th sixteenth transistor TR16b, a c-th sixteenth transistor TR-16c, a d-th sixteenth transistor TR16d, an e-th sixteenth transistor TR16e, and an f-th sixteenth transistor TR16f. However, embodiments of the present disclosure are not limited thereto, and the sixteenth transistors TR16a to TR16f may be implemented to include more than six transistors, or to include fewer than six transistors.

The a-th sixteenth transistor TR16a may be configured or connected to switch an electrical connection between the a-th second capacitor C2a and the second node SN2.

The b-th sixteenth transistor TR16b may be configured or connected to switch an electrical connection between the b-th second capacitor C2b and the second node SN2.

The c-th 16th transistor TR16 c may be configured or connected to switch an electrical connection between the c-th second capacitor C2c and the second node SN2.

The d-16th transistor TR16d may be configured or connected to switch an electrical connection between the d-th second capacitor C2d and the second node SN2.

The e-16th transistor TR16e may be configured or connected to switch an electrical connection between the e-th second capacitor C2e and the second node SN2.

The f-16th transistor TR16f may be configured or connected to switch an electrical connection between the f-th second capacitor C2f and the second node SN2.

When the sixteenth transistors TR16a to TR16f are turned on, by connecting the Q nodes Qa to Qf with the second node SN2, the pre-charged voltage and the boosted voltage may be provided to the Q nodes Qa to Qf. When the sixteenth transistors T16a to T16f are turned off, the electrical connection between the Q nodes Qa to Qf and the second node SN2 may be insulated to prevent the voltage of the neighboring Q node from fluctuating while an individual voltage is applied to each of the Q nodes Qa to Qf.

The second capacitors C2a to C2f may be configured or connected to maintain a potential difference between the Q nodes Qa to Qf and the fourth node SN4. In an embodiment, the second capacitors C2a to C2f are composed of or includes six capacitors, which may include an a-th second capacitor C2a, a b-th second capacitor C2b, a c-th second capacitor C2c, a d-th second capacitor C2d, an e-th second capacitor C2e, and an f-th second capacitor C2f. However, embodiments of the present disclosure are not limited thereto, and the second capacitors C2a to C2f may be implemented to include more than six capacitors, or to include fewer than six capacitors.

The a-th second capacitor C2a may include one electrode connected to the a-th Q node Qa and the other electrode connected to the fourth node SN4.

The b-th second capacitor C2b may include one electrode connected to the b-th Q node Qb and the other electrode connected to the fourth node SN4.

The c-th second capacitor C2c may include one electrode connected to the c-th Q node Qc and the other electrode connected to the fourth node SN4.

The d-th second capacitor C2d may include one electrode connected to the d-th Q node Qd and the other electrode connected to the fourth node SN4.

The e-th second capacitor C2e may include one electrode connected to the e-th Q node Qe and the other electrode connected to the fourth node SN4.

The f-th second capacitor C2f may include one electrode connected to the f-th Q node Qf and the other electrode connected to the fourth node SN4.

The second capacitors C2a to C2f may perform a function of controlling the i-th to (i+5)-th scan signals SCAN[i] to SCAN[i+5] to be stably output through the scan output terminals 841 to 846 by maintaining the voltage of the Q nodes Qa to Qf.

In an embodiment of the scan driving integrated circuit 800, seventeenth transistors TR17a to TR17f may be configured or connected to switch an electrical connection between the third to eighth clock terminals 833 to 838 and the first to sixth scan output terminals 841 to 846 in response to a voltage of a corresponding one of the Q nodes Qa to Qf. The first to sixth scan clock signals SC_CLK1 to SC_CLK6 may be input to the third to eighth clock terminals 833 to 838. In an embodiment, the seventeenth transistors TR17a to TR17f are composed of or include six transistors, which may include an a-th seventeenth transistor TR17a, a b-th seventeenth transistor TR17b, a c-th seventeenth transistor TR17c, a d-th seventeenth resistor TR17d, an e-th seventeenth transistor TR17e, and an f-th seventeenth transistor TR17f. However, embodiments of the present disclosure are not limited thereto, and the seventeenth transistors TR17a to TR17f may include more than six transistors, or may be implemented to include fewer than six transistors.

The a-th seventeenth transistor TR17a may be configured or connected to switch an electrical connection between the third clock terminal 833 and the first scan output terminal 841.

The b-th seventeenth transistor TR17b may be configured or connected to switch an electrical connection between the fourth clock terminal 834 and the second scan output terminal 842.

The c-th seventeenth transistor TR17c may be configured or connected to switch an electrical connection between the fifth clock terminal 835 and the third scan output terminal 843.

The d-th seventeenth transistor TR17d may be configured or connected to switch an electrical connection between the sixth clock terminal 836 and the fourth scan output terminal 844.

The e-th seventeenth transistor TR17e may be configured or connected to switch an electrical connection between the seventh clock terminal 837 and the fifth scan output terminal 845.

The f-th seventeenth transistor TR17f may be configured or connected to switch an electrical connection between the eighth clock terminal 838 and the sixth scan output terminal 846.

The seventeenth transistors TR17a to TR17f may function as output buffers for outputting the i-th to (i+5)-th scan signals SCAN[i] to SCAN[i+5].

In an embodiment of the scan driving integrated circuit 800, an eighteenth transistor TR18 may be configured or connected to switch an electrical connection between the first node SN1 and the third power supply terminal 823 in response to the voltage of the third node SN3. When the eighteenth transistor TR18 is turned on, a current path from the first node SN1 to the third power supply terminal 823 via the eighteenth transistor TR18 may be formed. Thereby, the voltage of the first node SN1 can be discharged. The eighteenth transistor TR18 may have a double gate structure in which two transistors are connected in series with each other while sharing a gate electrode. However, embodiments of the present disclosure are not limited thereto, and the eighteenth transistor TR18 may be implemented as one transistor.

In an embodiment of the scan driving integrated circuit 800, a nineteenth transistor TR19 may be configured or connected to switch an electrical connection between the second node SN2 and the fourth power supply terminal 824 in response to a signal input to the third carry terminal 813. When the nineteenth transistor TR19 is turned on, the voltage of the second node SN2 may be lowered to the second low voltage VSS2. Thereby, the first capacitor C1 may be discharged. The nineteenth transistor TR19 may have a double gate structure in which two transistors are connected in series with each other while sharing a gate electrode. However, embodiments of the present disclosure are not limited thereto, and the nineteenth transistor TR19 may be implemented as one transistor.

In an embodiment of the scan driving integrated circuit 800, as described above, the i-th to (i+5)-th scan signals SCAN[i] to SCAN[i+5] may be output through the first to sixth scan output terminals 841 to 846. Then, the N-th carry signal CR[N] may be output.

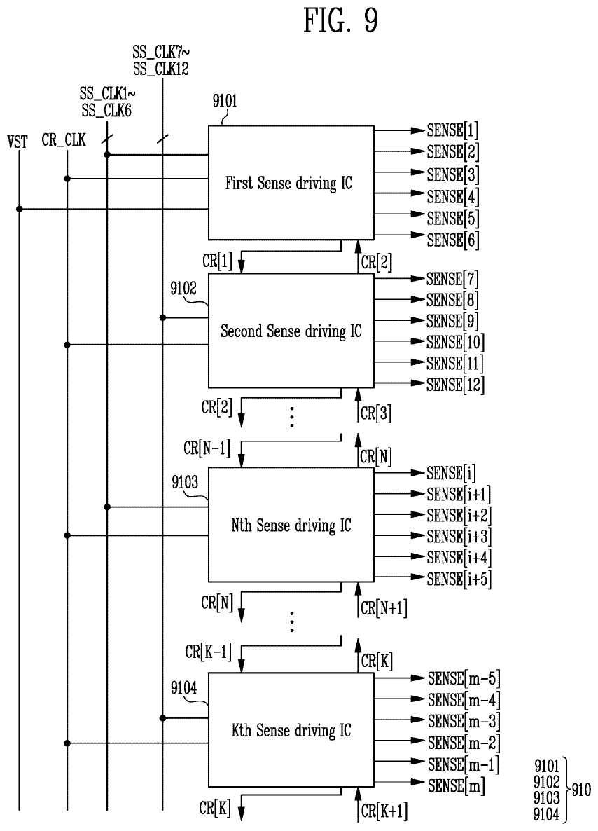

FIG. 9 is a block diagram of an embodiment of a sense driving circuit 910.

The sense driving circuit 910 may include a plurality of sense driving integrated circuits. Although four sense driving integrated circuits 9101 to 9104 of the sense driving circuit 910 are shown in FIG. 9 for ease of illustration and description, embodiments of the present disclosure are not limited thereto.

Each of the sense driving integrated circuits 9101 to 9104 corresponds to a stage of the sense driving circuit 910. An embodiment in which each of the sense driving integrated circuits 9101 to 9104 outputs two or more sense signals, for example, six sense signals, is shown in FIG. 9. However, embodiments of the present disclosure are not so limited, and each of the sense driving integrated circuits 9101 to 9104 may be configured to output more than six sense signals.

At least one of the sense driving integrated circuits 9101 to 9104 may receive at least six of the twelve sense clock signals SS_CLK1 through SS_CLK12. At least one of the sense driving integrated circuits 9101 to 9104 may receive a carry clock signal CR_CLK. At least one of the sense driving integrated circuits 9101 to 9104 may receive a start signal VST or a carry signal from a preceding sense driving integrated circuit. At least one of the sense driving integrated circuits 9101 to 9104 may receive a carry signal from a succeeding sense driving integrated circuit.

The sense driving circuit 910 may include a first sense driving integrated circuit 9101, a second sense driving integrated circuit 9102, an N-th (N is an integer greater 2) sense driving integrated circuit 9103, and a K-th (K is an integer greater N) sense driving integrated circuit 9104.

The first sense driving integrated circuit 9101 may receive the first to sixth sense clock signals SS_CLK1 to SS_CLK6 among the twelve sense clock signals SS_1 to SS_CLK12. The first sense driving integrated circuit 9101 may receive a carry clock signal CR_CLK. The first sense driving integrated circuit 9101 may receive a start signal VST. The first sense driving integrated circuit 9101 may receive a carry signal CR[2] from a subsequent second sense driving integrated circuit 9102.

The first sense driving integrated circuit 9101 may output first to sixth sense signals SENSE[1] to SENSE[6]. The first sense driving integrated circuit 9101 may output the carry signal CR[1].

The second sense driving integrated circuit 9102 may receive the seventh to twelfth sense clock signals SS_CLK7 to SS_CLK12 among the twelve sense clock signals SS_1 to SS_CLK 12. The second sense driving integrated circuit 9102 may receive the carry clock signal CR_CLK. The second sense driving integrated circuit 9102 may receive the carry signal CR[1] from the preceding first sense driving integrated circuit 9101. The second sense driving integrated circuit 9102 may receive the carry signal CR[3] from a subsequent third sense driving integrated circuit.

The second sense driving integrated circuit 9102 may output the seventh to twelfth sense signals SENSE[7] to SENSE[12]. The second sense driving integrated circuit 9102 may output a carry signal CR[2].

The N-th sense driving integrated circuit 9103 may receive the first to sixth sense clock signals SS_CLK1 to SS_CLK6 among the twelve sense clock signals SS_1 to SS_CLK12. The N-th sense driving integrated circuit 9103 may receive the carry clock signal CR_CLK. The N-th sense driving integrated circuit 9103 may receive the carry signal CR[N−1] from the preceding (N−1)-th sense driving integrated circuit. The N-th sense driving integrated circuit 9103 may receive the carry signal CR[N+1] from the following (N+1)-th sense driving integrated circuit.

The N-th sense driving integrated circuit 9103 may output i-th to (i+5)-th sense signals SENSE[i] to SENSE[i+5]. The N-th sense driving integrated circuit 9103 may output the carry signal CR[N].

The K-th sense driving integrated circuit 9104 may receive the seventh to twelfth sense clock signals SS_CLK7 to SS_CLK12 among the twelve sense clock signals SS_CLK1 to SS_CLK12. The K-th sense driving integrated circuit 9104 may receive the carry clock signal CR_CLK. The K-th sense driving integrated circuit 9104 may receive the carry signal CR[K−1] from the preceding (K−1)-th sense driving integrated circuit. The K-th sense driving integrated circuit 9104 may receive the carry signal CR[K+1] from the following (K+1)-th sense driving integrated circuit.

The K-th sense driving integrated circuit 9104 may output (m−5)-th to m-th sense signals SENSE[m−5] to SENSE [m]. The K-th sense driving integrated circuit 9104 may output the carry signal CR[K].

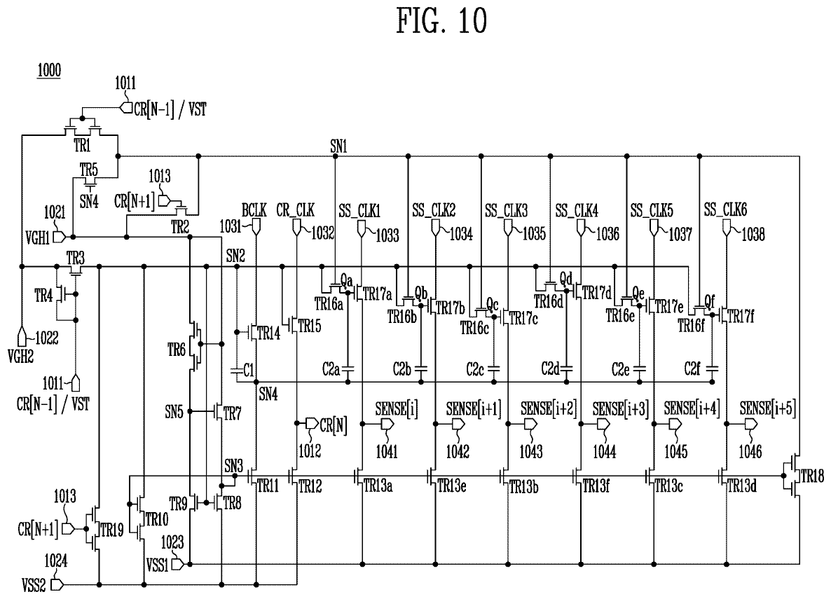

In FIG. 10, the N-th sense driving integrated circuit 9103 is shown as an example, and its configuration and driving method will be described in greater detail with reference to FIG. 10. The configuration of the N-th sense driving integrated circuit 9103 and the method of driving the same may be similarly applied to other sense driving integrated circuits included in the sense driving circuit 910.

FIG. 10 is an equivalent circuit diagram of a sense driving integrated circuit 1000 according to an embodiment.

Referring to FIG. 10, a sense driving integrated circuit 1000 according to embodiments of the present disclosure may include one or more terminals, one or more transistors, and one or more capacitors. The configuration of the sense driving integrated circuit 1000 according to an embodiment will hereinafter be described in detail.

In an embodiment of the sense driving integrated circuit 1000, a first transistor TR1 may be configured or connected to switch an electrical connection between the second power supply terminal 1022 and the first node SN1 in response to a signal input to the first carry terminal 1011. A start signal VST or a carry signal CR[N−1] of a previous stage may be input to the first carry terminal 1011. A second high voltage VGH2 may be applied to the second power supply terminal 1022. The second high voltage VGH2 may be a turn-on level voltage of the sixteenth transistors T16a to T16f. In an embodiment, the first transistor TR1 may have a double gate structure in which two transistors are connected in series with each other while sharing a gate electrode. However, embodiments of the present disclosure are not limited thereto, and the first transistor TR1 may be implemented as one transistor.

In an embodiment of the sense driving integrated circuit 1000, a second transistor TR2 may be configured or connected to switch an electrical connection between the first power supply terminal 1021 and the first node SN1 in response to a signal input to the third carry terminal 1013. The carry signal CR[N+1] of the following stage may be input to the third carry terminal 1013. A first high voltage VGH1 may be applied to the first power supply terminal 1021. The voltage level of the first high voltage VGH1 may be lower than the voltage level of the second high voltage VGH2. For example, the first high voltage VGH1 may be a turn-off level voltage of the sixteenth transistors T16a to T16f. The voltage level of the first high voltage VGH1 may be higher than that of the first low voltage VSS1.

In an embodiment of the sense driving integrated circuit 1000, a third transistor TR3 may be configured or connected to switch an electrical connection between the second power supply terminal 1022 and the second node SN2 in response to a signal input to the first carry terminal 1011.

In an embodiment of the sense driving integrated circuit 1000, a fourth transistor TR4 may include a gate electrode connected to the first carry terminal 1011. The fourth transistor TR4 may be configured or connected to switch an electrical connection between the third transistor TR3 and the first carry terminal 1011. When the start signal VST or the carry signal CR[N−1] of the previous stage is input, the third transistor TR3 and the fourth transistor TR4 may be turned on together. Thereby, the second high voltage VGH2 is applied to the second node SN2, so that the eighth transistor TR8, the ninth transistor TR9, the fourteenth transistor TR14, and the fifteenth transistor TR15 may be turned on.

The first to fourth transistors TR1 to TR4 may constitute a pre-charge unit (or a pre-charge circuit).

In an embodiment of the sense driving integrated circuit 1000, a fifth transistor TR5 may be configured or connected to switch an electrical connection between the first power supply terminal 1021 and the first node SN1 in response to a voltage applied to the fourth node SN4. When the fifth transistor TR5 is turned on, a current path may be formed at the first node SN1 in the direction of the first power supply terminal 1021 through the fifth transistor TR5. Thereby, the voltage of the first node SN1 may be discharged.

In an embodiment of the sense driving integrated circuit 1000, a sixth transistor TR6 may be configured or connected to switch an electrical connection between the first power supply terminal 1021 and the fifth node SN5 in response to a voltage input to the first power supply terminal 1021. The first high voltage VGH1 input to the first power supply terminal 1021 may be a turn-on level voltage of the sixth transistor TR6. In an embodiment, the sixth transistor TR6 may have a double gate structure in which two transistors are connected in series with each other while sharing a gate electrode. However, embodiments of the present disclosure are not limited thereto, and the sixth transistor TR6 may be implemented as one transistor.

In an embodiment of the sense driving integrated circuit 1000, a seventh transistor TR7 may be configured or connected to switch an electrical connection between the first power supply terminal 1021 and the third node SN3 in response to a voltage applied to the fifth node SN5. When the seventh transistor TR7 is turned on, a voltage corresponding to the first high voltage VGH1 is applied to the third node SN3, whereby the eleventh transistor TR11, the twelfth transistor TR12, the thirteenth transistors TR13a to TR13f, and the eighteenth transistor TR18 may be turned on.

In an embodiment of the sense driving integrated circuit 1000, an eighth transistor TR8 may be configured or connected to switch an electrical connection between the fourth power supply terminal 1024 and the third node SN3 in response to a voltage applied to the second node SN2. The second low voltage VSS2 may be applied to the fourth power supply terminal 1024. When the eighth transistor TR8 is turned on, the second low voltage VSS2 is applied to the third node SN3, so that the tenth transistor TR10, the eleventh transistor TR11, the twelfth transistor TR12, the thirteenth transistors TR13a to TR13f, and the eighteenth transistor TR18 may be turned off.

In an embodiment of the sense driving integrated circuit 1000, a ninth transistor TR9 may be configured or connected to switch an electrical connection between the third power supply terminal 1023 and the fifth node SN5 in response to a voltage applied to the second node SN2. The first low voltage VSS1 may be applied to the third power supply terminal 1023. The eighth transistor TR8 and the ninth transistor TR9 may be turned on together in response to the voltage of the second node SN2. When the ninth transistor TR9 is turned on, the first low voltage VSS1 is applied to the fifth node SN5, so that the seventh transistor TR7 may be turned off. Thereby, the first power supply terminal 1021 and the third node SN3 may be electrically insulated.

In an embodiment of the sense driving integrated circuit 1000, a tenth transistor TR10 may be configured or connected to switch an electrical connection between the second node SN2 and the fourth power supply terminal 1024 in response to a voltage applied to the third node SN3. When the tenth transistor TR10 is turned on, the second low voltage VSS2 may be applied to the second node SN2. The second low voltage VSS2 may be applied to one electrode of the first capacitor C1 electrically connected to the second node SN2. Thereby, the voltage of the second node SN2 may be discharged. The tenth transistor TR10 may have a double gate structure in which two transistors are connected in series with each other while sharing a gate electrode. However, embodiments of the present disclosure are not limited thereto, and the tenth transistor TR10 may be implemented as one transistor.

The sixth to tenth transistors TR6 to TR10 may constitute an inverter having the second node SN2 as an input node and the third node SN3 as an output node.

In an embodiment of the sense driving integrated circuit 1000, an eleventh transistor TR11 may be configured or connected to switch an electrical connection between the fourth node SN4 and the fourth power supply terminal 1024 in response to a voltage of the third node SN3. When the eleventh transistor TR11 is turned on, a current path from the fourth node SN4 to the fourth power supply terminal 1024 via the eleventh transistor TR11 may be formed. Thereby, the voltage of the fourth node SN4 may be discharged.

In an embodiment of the sense driving integrated circuit 1000, a twelfth transistor TR12 may be configured or connected to switch an electrical connection between the second carry terminal 1012 and the fourth power supply terminal 1024 in response to a voltage of the third node SN3. The carry signal CR[N] of the current stage may be output to the second carry terminal 1012. When the twelfth transistor TR12 is turned on, the second low voltage VSS2 may be output through the second carry terminal 1012.

In an embodiment of the sense driving integrated circuit 1000, thirteenth transistors TR13a to TR13f may be configured or connected to switch an electrical connection between the sense output terminals 1041 to 1046 and the third power supply terminal 1023 in response to a voltage of the third node SN3. In an embodiment, the thirteenth transistors TR13a to TR13f are composed of or includes six transistors, which may include an a-th thirteenth transistor TR13a, a b-th thirteenth transistor TR13b, a c-th thirteenth transistor TR13c, a d-th thirteenth transistor TR13d, an e-th thirteenth transistor TR13e, and an f-th thirteenth transistor TR13f. However, embodiments of the present disclosure are not limited thereto, and the thirteenth transistors TR13a to TR13f may be implemented to include more than six transistors, or to include fewer than six transistors.

The a-th thirteenth transistor TR13a may be configured or connected to switch an electrical connection between the first sense output terminal 1041, which outputs the i-th sense signal SENSE[i], and the third power supply terminal 1023.

The b-th thirteenth transistor TR13b may be configured or connected to switch an electrical connection between the second sense output terminal 1042, which outputs the (i+1)-th sense signal SENSE[i+1], and the third power supply terminal 1023.

The c-th transistor TR13c may be configured or connected to switch an electrical connection between the third sense output terminal 1043, which outputs the (i+2)-th sense signal SENSE[i+2], and the third power supply terminal 1023.

The d-th thirteenth transistor TR13d may be configured or connected to switch an electrical connection between the fourth sense output terminal 1044, which outputs the (i+3)-th sense signal SENSE[i+3], and the third power supply terminal 1023.

The e-th thirteenth transistor TR13e may be configured or connected to switch an electrical connection between the fifth sense output terminal 1045, which outputs the (i+4)-th sense signal SENSE[i+4], and the third power supply terminal 1023.

The f-th thirteenth transistor TR13f may be configured or connected to switch the electrical connection between the sixth sense output terminal 1046, which outputs the (i+5)-th sense signal SENSE[i+5], and the third power supply terminal 1023.

When the thirteenth transistors TR13a to TR13f are turned on, the first low voltage VSS1 may be output through the sense output terminals 1041 to 1046.

The eleventh transistor TR11, the twelfth transistor TR12, and the thirteenth transistors TR13a to TR13f may constitute a pull-down unit (or a pull-down circuit).

In an embodiment of the sense driving integrated circuit 1000, a fourteenth transistor TR14 may be configured or connected to switch an electrical connection between the first clock terminal 1031 and the fourth node SN4 in response to a voltage applied to the second node SN2. A boosting clock signal BCLK may be applied to the first clock terminal 1031. When the fourteenth transistor TR14 is turned on, the first clock terminal 1031 may be electrically connected to the fourth node SN4 via the fourteenth transistor TR14. When the boosting clock signal BCLK is applied to the fourth node SN4, the voltage of the second node SN2 may increase (or be boosted) by the coupling effect of the first capacitor C1.

In an embodiment of the sense driving integrated circuit 1000, a first capacitor C1 may include one electrode connected to the second node SN2 and the other electrode connected to the fourth node SN4. The first capacitor C1 may be configured to maintain a voltage difference between the second node SN2 and the fourth node SN4. The first capacitor C1 may be pre-charged by the second high voltage VGH2. When the voltage of the fourth node SN4 rises due to the boosting clock signal BCLK, the voltage of the second node SN2 may rise due to the coupling effect of the first capacitor C1.

The fourteenth transistor TR14 and the first capacitor C1 may constitute a boosting unit (or a boosting circuit).

In an embodiment of the sense driving integrated circuit 1000, a fifteenth transistor TR15 may be configured or connected to switch an electrical connection between the second clock terminal 1032 and the second carry terminal 1012 in response to a voltage of the second node SN2. The carry clock signal CR_CLK may be input to the second clock terminal 1032. When the fifteenth transistor TR15 is turned on, the carry clock signal CR_CLK may be output as the carry signal CR[N] of the current stage through the second carry terminal 1012. The fifteenth transistor TR15 may function as an output buffer for outputting the carry signal CR[N] of the current stage.

In an embodiment of the sense driving integrated circuit 1000, sixteenth transistors TR16a to TR16f may be configured or connected to switch an electrical connection between second capacitors C2a to C2f and the second node SN2 in response to the voltage of the first node SN1. In an embodiment, the sixteenth transistors TR16a to TR16f are composed of or include six transistors, which may include an a-th sixteenth transistor TR16a, a b-th sixteenth transistor TR16b, a c-th sixteenth transistor TR16c, a d-th sixteenth transistor TR16d, an e-th sixteenth transistor TR16e, and an f-th sixteenth transistor TR16f. However, embodiments of the present disclosure are not limited thereto, and the sixteenth transistors TR16a to TR16f may be implemented to include more than six transistors, or to include fewer than six transistors.

The a-th sixteenth transistor TR16a may be configured or connected to switch an electrical connection between the a-th second capacitor C2a and the second node SN2.

The b-th sixteenth transistor TR16b may be configured or connected to switch an electrical connection between the b-th second capacitor C2b and the second node SN2.

The c-th sixteenth transistor TR16c may be configured or connected to switch an electrical connection between the c-th second capacitor C2c and the second node SN2.

The d-th sixteenth transistor TR16d may be configured or connected to switch an electrical connection between the d-th second capacitor C2d and the second node SN2.

The e-th sixteenth transistor TR16e may be configured or connected to switch an electrical connection between the e-th second capacitor C2e and the second node SN2.

The f-th sixteenth transistor TR16f may be configured or connected to switch an electrical connection between the f-th second capacitor C2f and the second node SN2.

When the sixteenth transistors TR16a to TR16f are turned on, by connecting the Q nodes Qa to Qf with the second node SN2, the pre-charged voltage and the boosted voltage may be provided to the Q nodes Qa to Qf. When the sixteenth transistors T16a to T16f are turned off, the electrical connection between the Q nodes Qa to Qf and the second node SN2 may be insulated to prevent the voltage of the neighboring Q node from fluctuating while an individual voltage is applied to each of the Q nodes Qa to Qf.

In an embodiment of the sense driving integrated circuit 1000, the second capacitors C2a to C2f may be configured or connected to maintain a potential difference between the Q nodes Qa to Qf and the fourth node SN4. In an embodiment, the second capacitors C2a to C2f are composed of or include six capacitors, which may include an a-th second capacitor C2a, a b-th second capacitor C2b, a c-th second capacitor C2c, a d-th second capacitor C2d, an e-th second capacitor C2e, and an f-th second capacitor C2f. However, embodiments of the present disclosure are not limited thereto, and the second capacitors C2a to C2f may be implemented to include more than six capacitors, or to include fewer capacitors.

The a-th second capacitor C2a may include one electrode connected to the a-Q node Qa and the other electrode connected to the fourth node SN4.

The b-th capacitor C2b may include one electrode connected to the b-th Q node Qb and the other electrode connected to the fourth node SN4.

The c-th capacitor C2c may include one electrode connected to the c-th Q node Qc and the other electrode connected to the fourth node SN4.

The d-th capacitor C2d may include one electrode connected to the d-th Q node Qd and the other electrode connected to the fourth node SN4.

The e-th second capacitor C2e may include one electrode connected to the e-th Q node Qe and the other electrode connected to the fourth node SN4.

The f-th second capacitor C2f may include one electrode connected to the f-th Q node Qf and the other electrode connected to the fourth node SN4.

The second capacitors C2a to C2f may perform a function of controlling the i-th to (i+5)-th sense signals SENSE[i] to SENSE[i+5] to be stably output through the sense output terminals 1041 to 1046 by maintaining the voltage of the Q nodes Qa to Qf.

In an embodiment of the sense driving integrated circuit 1000, seventeenth transistors TR17a to TR17f may be configured or connected to switch an electrical connection between the third to eighth clock terminals 1033 to 1038 and the first to sixth sense output terminals 1041 to 1046 in response to a voltage of a corresponding one of the Q nodes Qa to Qf. First to sixth sense clock signals SS_CLK1 to SS_CLK6 may be input to the third to eighth clock terminals 1033 to 1038. In an embodiment, the seventeenth transistors TR17a to TR17f are composed of or include six transistors, which may include an a-th seventeenth transistor TR17a, a b-th seventeenth transistor TR17b, a c-th seventeenth transistor TR17c, a d-th seventeenth transistor TR17d, an e-th seventeenth transistor TR17e, and an f-th seventeenth transistor TR17f. However, embodiments of the present disclosure are not limited thereto, and the seventeenth transistors TR17a to TR17f may include more than six transistors, or may be implemented to include fewer than six transistors.

The a-th seventeenth transistor TR17a may be configured or connected to switch an electrical connection between the third clock terminal 1033 and the first sense output terminal 1041.

The b-th seventeenth transistor TR17b may be configured or connected to switch an electrical connection between the fourth clock terminal 1034 and the second sense output terminal 1042.

The c-th seventeenth transistor TR17c may be configured or connected to switch an electrical connection between the fifth clock terminal 1035 and the third sense output terminal 1043.

The d-th seventeenth transistor TR17d may be configured or connected to switch an electrical connection between the sixth clock terminal 1036 and the fourth sense output terminal 1044.

The e-th seventeenth transistor TR17e may be configured or connected to switch an electrical connection between the seventh clock terminal 1037 and the fifth sense output terminal 1045.

The f-th seventeenth transistor TR17f may be configured or connected to switch an electrical connection between the eighth clock terminal 1038 and the sixth sense output terminal 1046.

The seventeenth transistors TR17a to TR17f may function as output buffers for outputting the i-th to (i+5)-th sense signals SENSE[i] to SENSE[i+5].

In an embodiment of the sense driving integrated circuit 1000, an eighteenth transistor TR18 may be configured or connected to switch an electrical connection between the first node SN1 and the third power supply terminal 1023 in response to the voltage of the third node SN3. When the eighteenth transistor TR18 is turned on, a current path from the first node SN1 to the third power supply terminal 1023 via the eighteenth diode TR18 may be formed. Thereby, the voltage of the first node SN1 may be discharged. The eighteenth transistor TR18 may have a double gate structure in which two transistors are connected in series with each other while sharing a gate electrode. However, embodiments of the present disclosure are not limited thereto, and the eighteenth transistor TR18 may be implemented as one transistor.

In an embodiment of the sense driving integrated circuit 1000, a nineteenth transistor TR19 may be configured or connected to switch an electrical connection between the second node SN2 and the fourth power supply terminal 1024 in response to a signal input to the third carry terminal 1013. When the nineteenth transistor TR19 is turned on, the voltage of the second node SN2 may be lowered to the second low voltage VSS2. Thereby, the first capacitor C1 may be discharged. The nineteenth transistor TR19 may have a double gate structure in which two transistors are connected in series with each other while sharing a gate electrode. However, embodiments of the present disclosure are not limited thereto, and the nineteenth transistor TR19 may be implemented as one transistor.

In an embodiment, as described above, the i-th to (i+5)-th sense signals SENSE[i] to SENSE[i+5] may be output through the first to sixth sense output terminals 1041 to 1046. Then, the N-th carry signal CR[N] may be output.

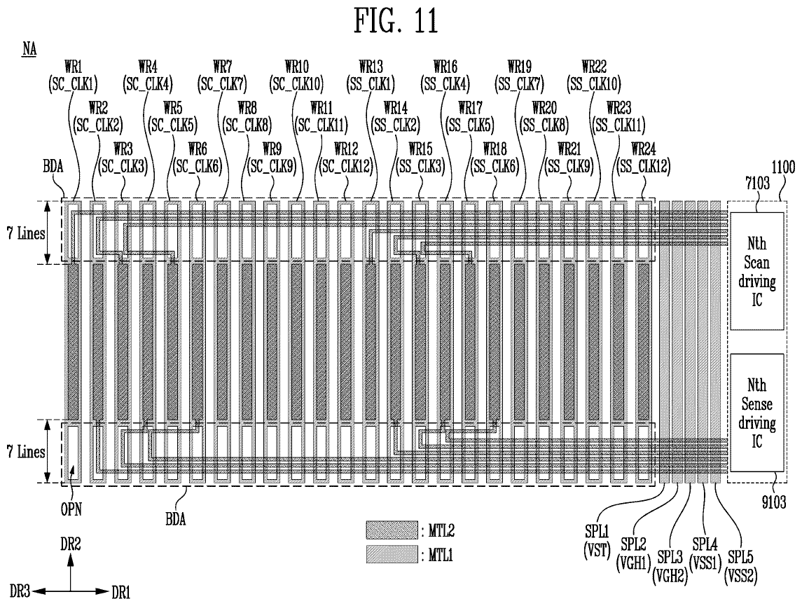

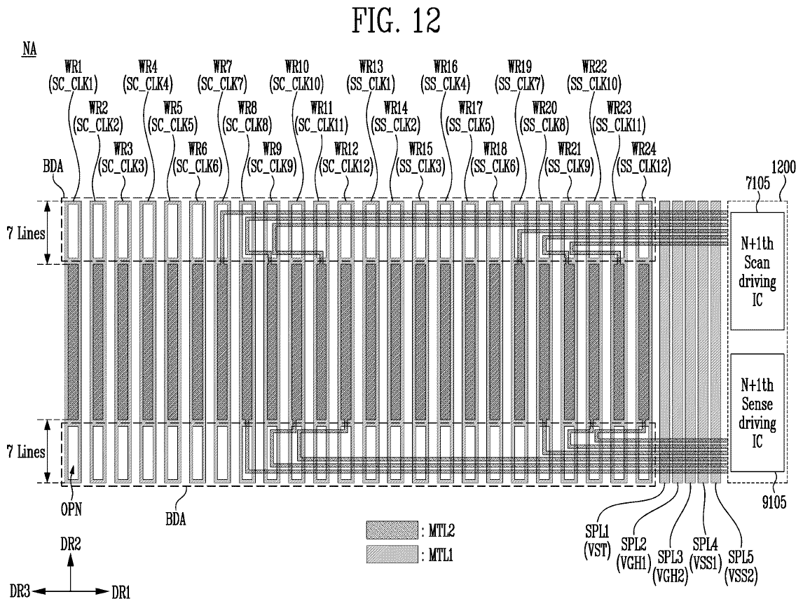

FIG. 11 is a diagram illustrating at least a portion of a non-display area NA according to an embodiment of the present disclosure. FIG. 12 is a diagram illustrating at least a portion of a non-display area NA according to an embodiment of the present disclosure.

Referring to FIG. 11 and FIG. 12, various wirings arranged in the non-display area NA and the N-th scan driving integrated circuit 7103, the (N+1)-th scan driving Integrated circuit 7105, the N-th sense driving circuit 9103, and the (N+1)-th sense driving Integrated circuit 9105 are illustrated. The N-th scan driving integrated circuit 7103 and the N-th sense driving integrated circuit 9103 may constitute the N-th stage circuit 1100. The (N+1)-th scan driving integrated circuit 7105 and the (N+1)-th sense driving integrated circuit 9105 may constitute the (N+1)-th stage circuit 1200.

In the non-display area NA, the first to twenty-fourth clock wirings WR1 to WR24, the first to fifth side signal wirings SPL1 to SPL5, and the stage circuits 1100 and 1200 may be sequentially arranged in the first direction DR1 in a plan view.

A start signal VST and power supply voltages VSS1, VSS2, VGH1, and VGH2 may be applied to the first to fifth side signal wirings SPL1 to SPL5. In an embodiment, for example, a start signal VST may be applied to the first side signal wiring SPL1. In such an embodiment, a first high voltage VGH1 may be applied to the second side signal wiring SPL2. In such an embodiment, a second high voltage VGH2 may be applied to the third side signal wiring SPL3. In such an embodiment, the first low voltage VSS1 may be applied to the fourth side signal wiring SPL4. In such an embodiment, the second low voltage VSS2 may be applied to the fifth side signal wiring SPL5.

The first to twelfth scan clock signals SC_CLK1 to SC_CLK12 and the first to twelfth sense clock signals SS_CLK1 to SS_CLK12 may be input to the first to twenty-fourth clock wirings WR1 to WR24. In an embodiment, the first to twelfth scan clock signals SC_CLK1 to SC_CLK12 may be input to the first to twelfth clock wirings WR1 to WR12, and the first to twelfth sense clock signals SS_CLK1 to SS_CLK12 may also be input to the thirteenth to twenty-fourth clock wirings WiR13 to WiR24. However, embodiments of the present disclosure are not limited thereto. In an embodiment, for example, the first to twelfth sense clock signals SS_CLK1 to SS_CLK12 may be input to the first to twelfth clock wirings WR1 to WR12, respectively, and the first to twelfth scan clock signals SC_CLK1 to SC_CLK12 may also be input to the thirteenth to twenty-fourth clock wirings WR13 to WR24, respectively. Hereinafter, for convenience of description, an embodiment in which first to twelfth scan clock signals SC_CLK1 to SC_CLK12 are input to first to twelfth clock wirings WR1 to WR12, respectively, and first to twelfth sense clock signals SS_CLK1 to SS_CLK12 are input to thirteenth to twenty-fourth clock wirings WR13 to WR24, respectively, will be described in detail as an example.

Each of the first to twelfth scan clock signals SC_CLK1 to SC_CLK12 may be input to a corresponding one of the first to twelfth clock wirings WR1 to WR12. In an embodiment, referring to FIGS. 11 and 12, the first scan clock signal SC_CLK1 may be input to the first clock wiring WR1. The second scan clock signal SC_CLK2 may be input to the second clock wiring WR2. The third scan clock signal SC_CLK3 may be input to the third clock wiring WR3. The fourth scan clock signal SC_CLK4 may be input to the fourth clock wiring WR4. The fifth scan clock signal SC_CLK5 may be input to the fifth clock wiring WR5. The sixth scan clock signal SC_CLK6 may be input to the sixth clock wiring WR6. The seventh scan clock signal SC_CLK7 may be input to the seventh clock wiring WR7. The eighth scan clock signal SC_CLK8 may be input to the eighth clock wiring WR8. The ninth scan clock signal SC_CLK9 may be input to the ninth clock wiring WR9. The tenth scan clock signal SC_CLK10 may be input to the tenth clock wiring WR10. The eleventh scan clock signal SC_CLK11 may be input to the eleventh clock wiring WR11. The twelfth scan clock signal SC_CLK12 may be input to the twelfth clock wiring WR12.

Each of the first to twelfth sense clock signals SS_CLK1 to SS_CLK12 may be input to a corresponding one of the thirteenth to twenty-fourth clock wirings WR13 to WR24. In an embodiment, referring to FIGS. 11 and 12, the first sense clock signal SS_CLK1 may be input to the thirteenth clock wiring WR13. The second sense clock signal SS_CLK2 may be input to the fourteenth clock wiring WR14. The third sense clock signal SS_CLK3 may be input to the fifteenth clock wiring WR15. The fourth sense clock signal SS_CLK4 may be input to the sixteenth clock wiring WR16. The fifth sense clock signal SS_CLK5 may be input to the seventeenth clock wiring WR17. The sixth sense clock signal SS_CLK6 may be input to the eighteenth clock wiring WR18. The seventh sense clock signal SS_CLK7 may be input to the nineteenth clock wiring WR19. The eighth sense clock signal SS_CLK8 may be input to the twentieth clock wiring WR20. The ninth sense clock signal SS_CLK9 may be input to the twenty-first clock wiring WR21. The tenth sense clock signal SS_CLK10 may be input to the twenty-second clock wiring WR22. The eleventh sense clock signal SS_CLK11 may be input to the twenty-third clock wiring WR23. The twelfth sense clock signal SS_CLK12 may be input to the twenty-fourth clock wiring WR24.

In an embodiment, the first to twenty-fourth clock wirings WR1 to WR24 may be sequentially located adjacent to each other in the first direction DR1. However, embodiments of the present disclosure are not limited thereto, and the arrangement of the first to twenty-fourth clock wirings WR1 to WR24 in the non-display area NA may be changed according to a design of a person skilled in the art.

Each of the first to twenty-fourth clock wirings WR1 to WR24 may have a double wiring structure. In an embodiment, for example, each of the first to twenty-fourth clock wirings WR1 to WR24 may include a first metal layer MTL1 and a second metal layer MTL2 that overlap each other in a vertical direction or a thickness direction of the display device 100. In an embodiment, the first metal layer MTL1 and the second metal layer MTL2 of each of the first to twenty-fourth clock wirings WR1 to WR24, may be directly or indirectly in contact with each other and electrically connected to each other. Each of the first metal layer MTL1 and the second metal layer MTL2 may extend generally in the second direction DR2. In an embodiment, the first metal layer MTL1 may be located above the second metal layer MTL2. In another embodiment, the first metal layer MTL1 may be located below the second metal layer MTL2. Accordingly, the resistances of the first to twenty-fourth clock wirings WR1 to WR24 may be reduced.

The second metal layer MTL2 included in the first to twenty-fourth clock wirings WR1 to WR24 may be bent by extending to an opening OPN defined through the first metal layer MTL1, and may extend in a direction extending in the first direction DR1 to be close to the stage circuits 1100 and 1200. The opening OPN may be defined by a removed part of the first metal layer MTL1. A region where the second metal layer MTL2 is bent in a bent region BDA, and the bent region BDA may at least partially overlap a region where the opening OPN of the first metal layer MTL1 is located.

In an embodiment, the distances from the first to twenty-fourth clock wirings WR1 to WR24 extending in the second direction DR2 to the stage circuits 1100 and 1200 may be different from each other. In a case where the distances from the first to the twenty-fourth clock wirings WR1 to WR24 to the stage circuits 1100 and 1200 becomes different from each other, the resistance of the respective wirings may thereby become different. Accordingly, the degree of voltage drop due to the IR drop in each of the first to twenty-fourth clock wirings WR1 to WR24 becomes different, such that the magnitude of the signal output from the stage circuits 1100 and 1200 may become different from each other.

Embodiments of the present disclosure may similarly set the degree to which the voltage drops by bending the clock wiring located close to the stage circuits 1100 and 1200 in a direction (e.g., the third direction DR3) away from the stage circuits 1100 and 1200. The third direction DR3 may be, for example, a direction opposite to the first direction DR1.

Referring to FIG. 11, first to sixth clock wirings WR1 to WR6 and thirteenth to eighteenth clock wirings WR13 to WR18 connected to the N-th stage circuit 1100 are shown.

In an embodiment, the odd-numbered clock wirings among the first to sixth clock wirings WR1 to WR6 may extend in the direction of the bent region BDA located on the upper side, and the even-numbered clock wirings may extend in the directions of the bent region BDA located on the lower side. In an embodiment, for example, the first clock wiring WR1, the third clock wiring WR3, and the fifth clock wiring WR5 may extend in the direction of the upper bent region BDA, and the second clock wiring WR2, the fourth clock wiring WR4, and the sixth clock wiring WR6 may extend in the directions of the lower bent region BDA. However, the embodiments of the present disclosure are not limited thereto, and the odd-numbered clock wirings may extend in the direction of the bent region BDA located at the lower side, and the even-numbered clock wirings may extend in a direction of the bent region BDA located at an upper side.

Hereinafter, the odd-numbered clock wirings among the first to sixth clock wirings WR1 to WR6 will be described.

The second metal layer MTL2 of the first clock wiring WR1 may extend in the second direction DR2 in the bent region BDA, and may be bent for the first time to extend in the first direction DR1.

The second metal layer MTL2 of the third clock wiring WR3 may extend in the second direction DR2 in the bent region BDA, may be bent for the first time to extend in the third direction DR3, may be bent for the second time to extend in the second direction DR2, and may be bent for the third time to extend in the first direction DR1. A region in which the third clock wiring WR3 is bent for the second time and extends in the second direction DR2 may overlap the opening OPN provided in the first metal layer MTL1 of the second clock wiring WR2.

The second metal layer MTL2 of the fifth clock wiring WR5 may extend in the second direction DR2 in the bent region BDA, may be bent for the first time to extend in the third direction DR3, may be bent for the second time to extend in the second direction DR2, and may be bent for the third time to extend in the first direction DR1. The region where the fifth clock wiring WR5 is bent for the second time and extends in the second direction DR2 may overlap the opening OPN provided in the first metal layer MTL1 of the third clock wiring WR3.

In an embodiment, the length of the region in which the second metal layer MTL2 of the first clock wiring WR1 is bent for the first time and extended in the first direction DR1, may be substantially equal to the sum of the length of a region in which the second metal layer MTL2 of the third clock wiring WR3 is bent for the first time and extended in the third direction DR3, and the length of a region in which the third clock wiring WR3 is bent for the third time and extended in the first direction DR1.

Similarly, the length of the region in which the second metal layer MTL2 of the first clock wiring WR1 is bent for the first time and extended in the first direction DR1, may be substantially the equal to the sum of the length of a region in which the second metal layer MTL2 of the fifth clock wiring WR5 is bent for the first time and extended in the third direction DR3, and the length of a region in which the fifth clock wiring WR5 is bent for the third time and extended in the first direction DR1.

In such an embodiment, a region where the third clock wiring WR3 is bent for the first time and extended in the third direction DR3 and a region where the fifth clock wiring WR5 is bent for the first time and extended in the third direction DR3 may be located adjacent to each other in the first direction DR1.

In an embodiment, the odd-numbered clock wirings among the thirteenth to eighteenth clock wirings WR13 to WR18 may extend in the direction of the bent region BDA located on the upper side, and the even-numbered clock wirings may extend in the direction of the bent region BDA located on the lower side. In an embodiment, for example, the thirteenth clock wiring WR13, the fifteenth clock wiring WR15, and the seventeenth clock wiring WR17 may extend in the direction of the bent region BDA located on the upper side, and the fourteenth clock wiring WR14, the sixteenth clock wiring WR16, and the eighteenth clock wiring WR18 may extend in the directions of the bent region BDA located on the lower side. However, the embodiments of the present disclosure are not limited thereto, and the odd-numbered clock wirings may extend in the direction of the bent region BDA located on the lower side, and the even-numbered clock wirings may extend in a direction of the bent region BDA located on the upper side.

Hereinafter, the odd-numbered clock wirings among the thirteenth to eighteenth clock wirings WR13 to WR18 will be described.

The second metal layer MTL2 of the thirteenth clock wiring WR13 may extend in the second direction DR2 in the bent region BDA and may be bent for the first time to extend in the first direction DR1.

The second metal layer MTL2 of the fifteenth clock wiring WR15 may extend in the second direction DR2 in the bent region BDA, may be bent for the first time to extend in the third direction DR3, may be bent for the second time to extend in the second direction DR2, and may be bent for the third time to extend in the first direction DR1. The region where the fifteenth clock wiring WR15 is bent for the second time and extends in the second direction DR2 may overlap the opening OPN provided in the first metal layer MTL1 of the fourteenth clock wiring WR14.

The second metal layer MTL2 of the seventeenth clock wiring WR17 may extend in the second direction DR2 in the bent region BDA, may be bent for the first time to extend in the third direction DR3, may be bent for the second time to extend in the second direction DR2, and may be bent for the third time to extend in the first direction DR1. The region in which the seventeenth clock wiring WR17 is bent for the second time and extends in the second direction DR2 may overlap the opening OPN provided in the first metal layer MTL1 of the sixteenth clock wirings WR16.

In an embodiment, the length of the region in which the second metal layer MTL2 of the thirteenth clock wiring WR13 is bent and extends in the first direction DR1, may be substantially the same a sum of the length of a region in which the first metal layer MTL1 of the fifteenth clock wiring WR15 is bent for the first time and extends in a third direction DR3, and the length of a region in which the fifteenth clock wiring WR15 is bent for the third time and extends in a first direction DR1.

Similarly, the length of the region in which the second metal layer MTL2 of the thirteenth clock wiring WR13 is bent and extends in the first direction DR1, may be substantially the same as the a sum of the length of a region in which the second metal layer MTL2 of the seventeenth clock wiring WR17 is bent for the first time and extends in the third direction DR3, and the length of a region in which the seventeenth clock wiring WR17 is bent for the third time and extends in the first direction DR1.

In such an embodiment, a region where the fifteenth clock wiring WR15 is bent for the first time and extends in the third direction DR3, and a region where the seventeenth clock wiring WR17 is bent for the first time and extends in the third direction DR3 may be located adjacent to each other in the first direction DR1.

In such an embodiment, on the first direction DR1 from the region in which the third clock wiring WR3 is bent for the first time and extends in the third direction DR3, there may be all the regions where the fifth clock wiring WR5 is bent for the first time and extends in the third direction DR3, where fifteenth clock wiring WR15 is bent for the first time and extends in the third direction DR3, and where the seventeenth clock wiring WR17 is bent for the first time and extends in the third direction DR3. Thereby, seven horizontal wirings including the second metal layer MTL2 are located in one bent region BDA, so that the size of the bent region BDA may be minimized.

Hereinafter, the even-numbered clock wirings among the first to sixth clock wirings WR1 to WR6 will be described.

The second metal layer MTL2 of the second clock wiring WR2 may extend in a direction opposite to the second direction DR2 in the bent region BDA, and may be bent for the first time to extend in the first direction DR1.

The second metal layer MTL2 of the fourth clock wiring WR4 may extend in a direction opposite to the second direction DR2 in the bent region BDA, be bent for the first time to extend in the third direction DR3, be bent for the second time to extend in a direction opposite the second direction DR2, and be bent for the third time to extend in the first direction DR1. A region in which the fourth clock wiring WR4 is bent for the second time and extends in a direction opposite to the second direction DR2, may overlap the opening OPN provided in the first metal layer MTL1 of the third clock wiring WR3.

The second metal layer MTL2 of the sixth clock wiring WR6 may extend in a direction opposite to the second direction DR2 in the bent region BDA, be bent for the first time to extend in the third direction DR3, be bent for the second time to extend in a direction opposite to the second direction DR2, and be bent for the third time to extend in the first direction DR1. A region in which the sixth clock wiring WR6 is bent for the second time and extends in a direction opposite to the second direction DR2, may overlap the opening OPN provided in the first metal layer MTL1 of the fourth clock wiring WR4.

In an embodiment, the length of the region in which the second metal layer MTL2 of the second clock wiring WR2 is bent for the first time and extends in the first direction DR1, may be substantially the same as a sum of the length of a region in which the first metal layer MTL1 of the fourth clock wiring WR4 is bent for the first time and extends in a third direction DR3, and the length of a region in which the fourth clock wiring WR4 is bent for the third time and extends in the first direction DR1.

Similarly, the length of the region in which the second metal layer MTL2 of the second clock wiring WR2 is bent and extends in the first direction DR1 may be substantially the same as a sum of the length of a region in which the first metal layer MTL1 of the sixth clock wiring WR6 is bent for the first time and extends in a third direction DR3, and the length of a region in which the sixth clock wirings WR6 are bent for the third time and extends in a first direction DR1.

In such an embodiment, a region where the third clock wiring WR3 is bent for the first time and extends in the third direction DR3 and a region where the fifth clock wiring WR5 is bent for the first time and extends in the third direction DR3 may be located adjacent to each other in the first direction DR1.

Hereinafter, even-numbered clock wirings among the thirteenth to eighteenth clock wirings WR13 to WR18 will be described.

The second metal layer MTL2 of the fourteenth clock wiring WR14 may extend in a direction opposite to the second direction DR2 in the bent region BDA, and may be bent for the first time to extend in the first direction DR1.

The second metal layer MTL2 of the sixteenth clock wiring WR16 may extend in a direction opposite to the second direction DR2 in the bent region BDA, be bent for the first time to extend in the third direction DR3, be bent for the second time to extend in the second direction DR2, and be bent for the third time to extend in the first direction DR1. A region in which the sixteenth clock wiring WR16 is bent for the second time and extends in the second direction DR2 may overlap the opening OPN provided in the first metal layer MTL1 of the fifteenth clock wiring WR15.

The second metal layer MTL2 of the eighteenth clock wiring WR18 may extend in a direction opposite to the second direction DR2 in the bent region BDA, be bent for the first time to extend in the third direction DR3, be bent for the second time to extend in a direction opposite to the second direction DR2, and be bent for the third time to extend in the first direction DR1. A region in which the eighteenth clock wiring WR18 is bent for the second time and extends in the second direction DR2 may overlap the opening OPN provided in the first metal layer MTL1 of the seventeenth clock wiring WR17.

In an embodiment, the length of the region in which the second metal layer MTL2 of the fourteenth clock wiring WR14 is bent and extends in the first direction DR1, may be substantially the same as a sum of the length of a region in which the first metal layer MTL1 of the sixteenth clock wirings WR16 is bent for the first time and extends in a third direction DR3 and the length of a region in which the sixteenth clock wiring WR16 is bent for the third time and extends in a first direction DR1.

Similarly, the length of the region in which the second metal layer MTL2 of the fourteenth clock wiring WR14 is bent and extends in the first direction DR1 may be substantially the same as a sum of the length of a region in which the second metal layer MTL2 of the eighteenth clock wiring WR18 is bent and extends in the third direction DR3 and the length of a region in which the eighteenth clock wiring WR18 is bent for the third time and extends in a first direction DR1.

In such an embodiment, a region where the sixteenth clock wiring WR16 is bent for the first time and extends in the third direction DR3 and a region where the eighteenth clock wiring WR18 is bent for the first time and extends in the third direction DR3 may be located adjacent to each other in the first direction DR1.

In such an embodiment, on the first direction DR1 from the region in which the fourth clock wiring WR4 is bent for the first time and extends in the third direction DR3, there may be all the regions in which the sixth clock wiring WR6 is bent for the first time and extends in the third direction DR3, in which a sixteenth clock wiring WR16 is bent for the first time and extends in the third direction DR3, and in which an eighteenth clock wiring WR18 is bent for the first time and extends in the third direction DR3. Thereby, seven horizontal wirings including the second metal layer MTL2 are located in one bent region BDA, so that the size of the bent region BDA may be minimized. In addition, the magnitude difference in resistance among the first to sixth clock wirings WR1 to WR6 may be reduced, and the magnitude difference in resistance among the thirteenth to eighteenth clock wirings WR13 to WR18 may be reduced.

Referring to FIG. 12, the seventh to twelfth clock wirings WR7 to WR12 and the nineteenth to twenty-fourth clock wirings WR19 to WR24 may be connected to the (N+1)-th stage circuit 1200 in at least a part of the non-display area NA.

The seventh to twelfth clock wirings WR7 to WR12 may be connected to the (N+1)-th stage circuit 1200, similar to the first to sixth clock wirings WR1 to WR6 being connected to the N-th stage circuit 1100. The nineteenth to twenty-fourth clock wirings WR19 to WR24 may be connected to the (N+1)-th stage circuit 1200, similar to the thirteenth to eighteenth clock wirings WR13 to WR18 being connected to the N-th stage circuit 1100.

Therefore, the description of the seventh to twelfth clock wirings WR7 to WR12 is replaced by the description of the first to sixth clock wirings WR1 to WR6 described above, and the description of the nineteenth to twenty-fourth clock wirings WR19 to WR24 is replaced by the explanation of the thirteenth to eighteenth clock wirings WR13 to WR18 described above.

In such an embodiment, the size of the bent region BDA may be minimized. In addition, the magnitude difference in resistance among the seventh to twelfth clock wirings WR7 to WR12 may be reduced, and the magnitude difference in resistance among the nineteenth to twenty-fourth clock wirings WR19 to WR24 may be reduced.

Referring to FIG. 11 and FIG. 12, by increasing the area of the region where the first metal layer MTL1 and the second metal layer MTL2 overlap in each of the first to twenty-fourth clock wirings WR1 to WR24, the overall resistance of the first to twenty-fourth clock wirings WR1 to WR24 may be reduced, which may be desired in terms of power consumption.

The first to fifth side signal wirings SP1 to SP5 may include a first metal layer MTL1.

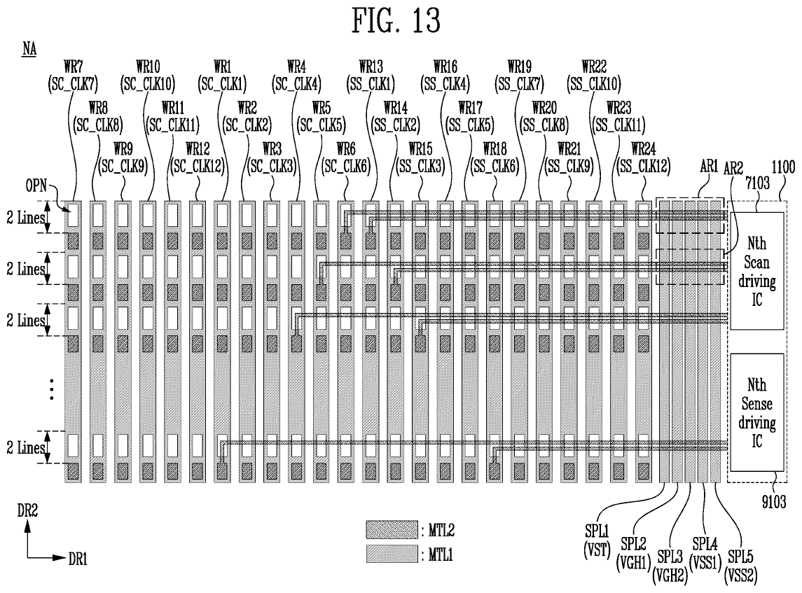

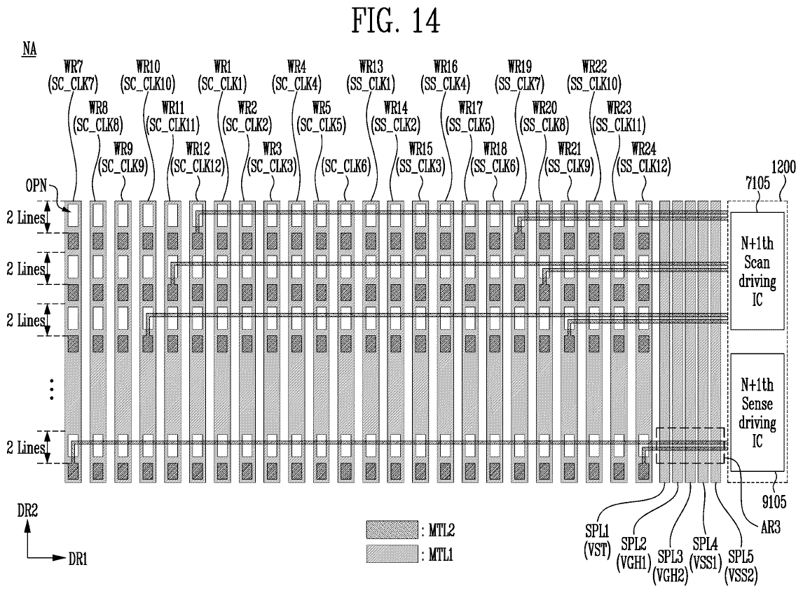

FIG. 13 is a diagram illustrating at least a portion of a non-display area NA according to another embodiment of the present disclosure. FIG. 14 is a diagram illustrating at least a portion of a non-display area NA according to another embodiment of the present disclosure.

Referring to FIG. 13, in another embodiment, the first to the twenty-fourth clock wirings WR1 to WR24 are arranged, the arrangement of the first to the twelfth clock wirings WR1 to WR12 may be different that described above with reference to FIG. 11 and FIG. 12.

In an embodiment, for example, from the left end of the non-display area NA, the seventh to twelfth clock wirings WR7 to WR12 may be sequentially arranged adjacent to each other in the first direction DR1, and the first to sixth clock wirings WR1 to WR6 may be sequentially arranged adjacent to each other in the first direction DR1. In the first direction DR1 from the sixth clock wiring WR6, the thirteenth to twenty-fourth clock wirings WR13 to WR24 may be sequentially arranged.

Referring to FIG. 13, the second metal layer MTL2 of any one of the first to sixth clock wirings WR1 to WR6 and the second metal layer MTL2 of any one of the thirteenth to eighteenth clock wirings WR13 to WR18 may be paired to extend in the second direction DR2. The second metal layer MTL2 extending in the second direction DR2 may be bent in the first direction DR1 in the opening OPN of the first metal layer MTL1 and connected to the N-th stage circuit 1100.

In an embodiment, as shown in FIG. 13, the sixth clock wiring WR6 and the thirteenth clock wiring WR13 may form a pair. The fifth clock wiring WR5 and the fourteenth clock wiring WR14 may form a pair. The fourth clock wiring WR4 and the fifteenth clock wiring WR15 may form a pair. The third clock wiring WR3 and the sixteenth clock wiring WR16 may form a pair. The second clock wiring WR2 and the seventeenth clock wiring WR17 may form a pair. The first clock wiring WR1 and the eighteenth clock wiring WR18 may form a pair.

The second metal layer MTL2 of each of the two paired clock wirings extends in the first direction DR1 and may overlap the first to fifth side signal wirings SPL1 to SPL5 in the vertical direction.

Referring to FIG. 14, the second metal layer MTL2 of any one of the seventh to twelfth clock wirings WR7 to WR12 and the second metal layer MTL2 of any one of the nineteenth to twenty-fourth clock wirings WR19 to WR24 may be paired to extend in the second direction DR2. The second metal layer MTL2 extending in the second direction DR2 may be bent in the first direction DR1 in the opening OPN of the first metal layer MTL1 to be connected to the (N+1)-th stage circuit 1200.

In an embodiment, as shown in FIG. 14, the twelfth clock wiring WR12 and the nineteenth clock wiring WR19 may form a pair. The eleventh clock wiring WR11 and the twentieth clock wiring WR20 may form a pair. The tenth clock wiring WR10 and the twenty-first clock wiring WR21 may form a pair. The ninth clock wiring WR9 and the twenty-second clock wiring WR22 may form a pair. The eighth clock wiring WR8 and the twenty-third clock wiring WR23 may form a pair. The seventh clock wiring WR7 and the twenty-fourth clock wiring WR24 may form a pair.

The second metal layer MTL2 of each of the two paired clock wirings extends in the first direction DR1 and may overlap the first to fifth side signal wirings SPL1 to SPL5 in the vertical direction.

In such an embodiment, in each of the regions in which the first to the twenty-fourth clock wirings WR1 to WR24 are paired and the second metal layer MTL2 extends in the first direction DR1, two horizontal wirings may be located.

In an embodiment, referring to FIGS. 13 and 14, the sixth clock wiring WR6 among the first to twelfth clock wirings WR1 to WR12 is located relatively close to the stage circuits 1100 and 1200. In such an embodiment, the seventh clock wiring WR7 is located relatively far from the stage circuits 1100 and 1200. Therefore, to reduce the difference in resistance value thereby, the first to twelfth clock wirings WR1 to WR12 may have different widths in the second direction DR2 depending on the length of the second metal layer MTL2 extending in the first direction DR1. In an embodiment, for example, as the length of the second metal layer MTL2 extending in the first direction DR1 increases, the width of the first to twelfth clock wirings WR1 to WR12 in the second direction DR2 may decrease.

Similarly, the twelfth clock wiring WR12 of the thirteenth to twenty-fourth clock wirings WR13 to WR24 is located relatively close to the stage circuits 1100 and 1200. In such an embodiment, the thirteenth clock wiring WR13 is located relatively far from the stage circuits 1100 and 1200. Therefore, to reduce the difference in resistance value thereby, the thirteenth to twenty-fourth clock wirings WR13 to WR24 may have different widths in the second direction DR2 depending on the length of the second metal layer MTL2 extending in the first direction DR1. In an embodiment, for example, the longer the length of the second metal layer MTL2 extending in the first direction DR1 is, the smaller the width in the second direction DR2 of the thirteenth to twenty-fourth clock wirings WR13 to WR24 may be.

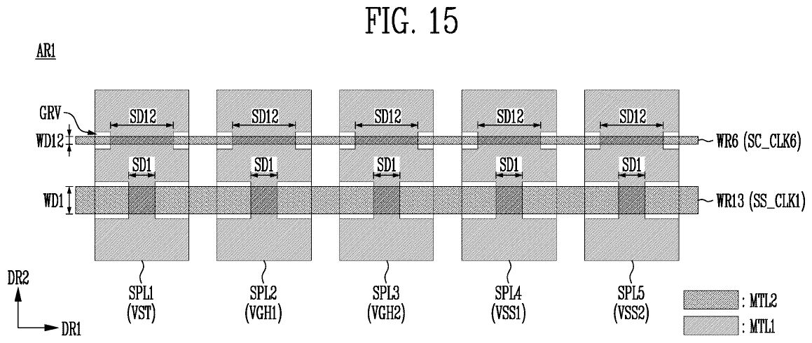

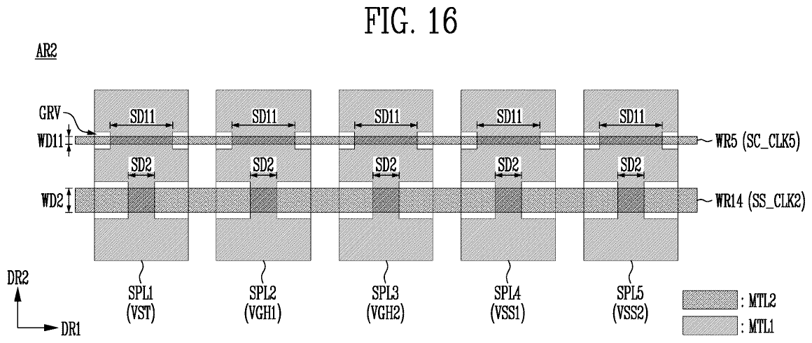

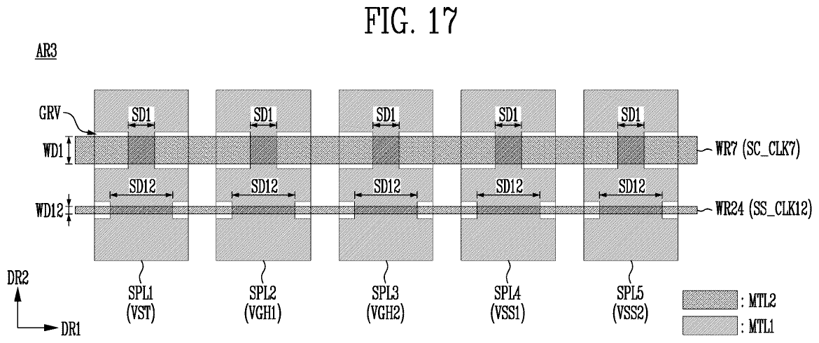

FIG. 15 is a diagram showing the first area AR1 of FIG. 13. FIG. 16 is a diagram showing the second area AR2 of FIG. 13. FIG. 17 is a diagram showing the third area AR3 of FIG. 14.

In an embodiment, the first to third areas AR1 to AR3 are areas that vertically overlap the side signal wirings SPL1 to SP5. The first to third areas AR1 to AR3 shown in FIGS. 13 and 14 will hereinafter be described in detail with reference to FIGS. 15 to 17.

Referring to FIG. 15, the first area AR1 is an area in which the second metal layer MTL2 of the sixth clock wiring WR6 and the second metal layer MTL2 of the thirteenth clock wiring WR13 extend in the first direction DR1.

The sixth clock wiring WR6 is a clock wiring located closest to the stage circuits 1100 and 1200 among the first to twelfth clock wirings WR1 to WR12. In this case, the width of the sixth clock wiring WR6 in the second direction DR2 may have a twelfth longitudinal width WD12. This may be the smallest value among the widths of the second metal layer MTL2 extending in the first direction DR1 in each of the first to twelfth clock wirings WR1 to WR12.

The thirteenth clock wiring WR13 is a clock wiring located farthest to the stage circuits 1100 and 1200 among the thirteenth to twenty-fourth clock wirings WR13 to WR24. In this case, the width of the thirteenth clock wiring WR13 in the second direction DR2 may have a first longitudinal width WD1. This may be the largest value among the widths of the second metal layer MTL2 extending in the first direction DR1 in each of the thirteenth to twenty-fourth clock wirings WR13 to WR24.

In an embodiment, each of the first to fifth side signal wirings SPL1 to SPL5 may be provided with a predetermined groove GRV in the first metal layer MTL1. The area of the region where the first metal layer MLT1 of each of the first to fifth side signal wirings SPL1 to SPL5 overlaps the second metal layer MTL2 of the first to twenty-fourth clock wirings WR1 to WR24 may be controlled by the groove GRV.

Referring to FIG. 15, in a region where at least one of the first to fifth side signal wirings SPL1 to SPL5 overlaps the sixth clock wiring WR6, a width in the first direction DR1 may be a twelfth lateral width SD12. Accordingly, the area of the region where the sixth clock wiring WR6 and at least one of the first to fifth side signal wirings SPL1 to SPL5 overlap each other may be defined as a value obtained by multiplying the twelfth longitudinal width WD12 by the twelfth lateral width SD12.

Then, in a region where at least one of the first to fifth side signal wirings SPL1 to SPL5 overlaps the thirteenth clock wiring WR13, a width in the first direction DR1 may be the first lateral width SD1. Accordingly, the area of the region where the thirteenth clock wiring WR13 overlaps at least one of the first to fifth side signal wirings SPL1 to SPL5 may be defined as a value obtained by multiplying the first longitudinal width WD1 by the first lateral width SD1.

In the above embodiment, the value obtained by multiplying the twelfth longitudinal width WD12 by the twelfth lateral width SD12 may be substantially equal to the value obtained by multiplying the first longitudinal width WD1 by the first lateral width SD1. Thereby, the values of the capacitances formed by the first to fifth side signal wirings SPL1 to SPL5 of the sixth clock wiring WR6 and the thirteenth clock wiring WR13 may be controlled to be substantially the same as each other.

Referring to FIG. 16, the second area AR2 is an area in which the second metal layer MTL2 of the fifth clock wiring WR5 and the second metal layer MTL2 of the fourteenth clock wiring WR14 extend in the first direction DR1.

The fifth clock wiring WR5 is a clock wiring located second closest to the stage circuits 1100 and 1200 among the first to twelfth clock wirings WR1 to WR12. In this case, the width of the fifth clock wiring WR5 in the second direction DR2 may have an eleventh longitudinal width WD11. This may be the second smallest value of the width of the second metal layer MTL2 extending in the first direction DR1 in each of the first to twelfth clock wirings WR1 to WR12.

The fourteenth clock wiring WR14 is a clock wiring located second farthest from the stage circuits 1100 and 1200 among the thirteenth to twenty-fourth clock wirings WR13 to WR24. In this case, the width of the fourteenth clock wiring WR14 in the second direction DR2 may have a second longitudinal width WD2. This may be the second largest value of the width of the second metal layer MTL2 extending in the first direction DR1 in each of the thirteenth to twenty-fourth clock wirings WR13 to WR24.

Referring to FIG. 16, in a region where at least one of the first to fifth side signal wirings SPL1 to SPL5 overlaps the fifth clock wiring WR5, a width in the first direction DR1 may be an eleventh lateral width SD11. Accordingly, the area of the region where the fifth clock wiring WR5 overlaps at least one of the first to fifth side signal wirings SPL1 to SPL5 may be defined as a value obtained by multiplying the eleventh longitudinal width WD11 by the eleventh lateral width SD11.

Then, in a region where at least one of the first to fifth side signal wirings SPL1 to SPL5 overlaps the fourteenth clock wiring WR14, a width in the first direction DR1 may be the second lateral width SD2. Accordingly, the area of the region where the fourteenth clock wiring WR14 overlaps at least one of the first to fifth side signal wirings SPL1 to SPL5 may be defined as a value obtained by multiplying the second longitudinal width WD2 by the second lateral width SD2.

In an embodiment, as described above, the value obtained by multiplying the eleventh longitudinal width WD11 by the eleventh lateral width SD11 may be substantially equal to the value obtained by multiplying the second longitudinal width WD2 by the second lateral width SD2. Thereby, the values of the capacitances formed by the first to fifth side signal wirings SPL1 to SPL5 of the fifth clock wiring WR5 and the fourteenth clock wiring WR14 may be controlled to be substantially the same.

Referring to FIG. 17, the third area AR3 is an area in which the second metal layer MTL2 of the seventh clock wiring WR7 and the second metal layer MTL2 of the twenty-fourth clock wiring WR24 extend in the first direction DR1.

The seventh clock wiring WR7 is a clock wiring located farthest from the stage circuits 1100 and 1200 among the first to twelfth clock wirings WR1 to WR12. In this case, the width of the seventh clock wiring WR7 in the second direction DR2 may have a first longitudinal width WD1. This may be the largest value among the widths of the second metal layer MTL2 extending in the first direction DR1 in each of the first to twelfth clock wirings WR1 to WR12.

The twenty-fourth clock wiring WR24 is a clock wiring located closest to the stage circuits 1100 and 1200 among the thirteenth to twenty-fourth clock wirings WR13 to WR24. In this case, the width of the twenty-fourth clock wiring WR24 in the second direction DR2 may have a twelfth longitudinal width WD12. This may be the smallest value among the widths of the second metal layer MTL2 extending in the first direction DR1 in each of the thirteenth to twenty-fourth clock wirings WR13 to WR24.

Referring to FIG. 17, in a region where at least one of the first to fifth side signal wirings SPL1 to SPL5 overlaps the seventh clock wiring WR7, a width in the first direction DR1 may be the first lateral width SD1. Accordingly, the area of the region where the seventh clock wiring WR7 overlaps at least one of the first to fifth side signal wirings SPL1 to SPL5 may be defined as a value obtained by multiplying the first longitudinal width WD1 by the first lateral width SD1.

Then, in a region where at least one of the first to fifth side signal wirings SPL1 to SPL5 overlaps the twenty-fourth clock wiring WR24, a width in the first direction DR1 may be a twelfth lateral width SD12. Accordingly, the area of the region where the twenty-fourth clock wiring WR24 overlaps at least one of the first to fifth side signal wirings SPL1 to SPL5 may be defined as a value obtained by multiplying the twelfth longitudinal width WD12 by the twelfth lateral width SD12.

Thereby, the width in the second direction DR2 of each of the two horizontally-lined (or laterally-lined) regions described with reference to FIGS. 13 and 14 may be substantially the same as each other.

In this embodiment, the capacitance formed in the region where each of the first to twelfth clock wirings WR1 to WR12 overlaps the first to fifth side signal wirings SPL1 to SPL5 may all be controlled to be the same (or substantially the same). In addition, the capacitance formed in the region where each of the thirteenth to twenty-fourth clock wirings WR13 to WR24 overlaps the first to fifth side signal wirings SPL1 to SPL5 may all be controlled to be the same (or substantially the same).

Thereby, the resistance between the first to twelfth clock wirings WR1 to WR12 may be configured to be substantially the same, and the resistance between the thirteenth to twenty-fourth clock wirings WR13 to WR24 may be configured to are substantially the same as each other.

In addition, capacitance values between the first to twenty-fourth clock wirings WR1 to WR24 may be configured to be substantially the same as each other.

Accordingly, the time delay that may occur in the first to twelfth clock wirings WR1 to WR12 may be controlled to be substantially the same as each other. Similarly, a time delay that may occur in the thirteenth to twenty-fourth clock wirings WR13 to WR24 may be controlled to be substantially the same as each other. In this way, the display quality may be improved.

Further, according to embodiments of the present disclosure, a space provided between the clock wirings WR1 to WR24 and the stage circuits 1100 and 1200 to make the lengths of the clock wirings WR1 to WR24 the same is removed, so that a narrow bezel of the display device 100 (see FIG. 1) or the display panel 110 (see FIG. 1) may be implemented.

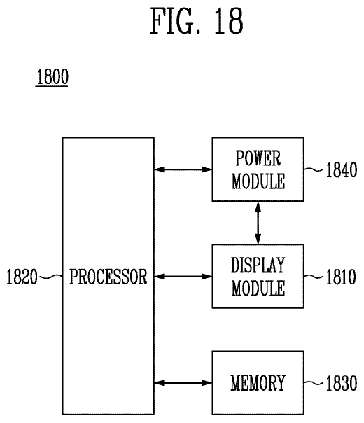

FIG. 18 is a block diagram of an electronic device 1800 according to an embodiment of the present disclosure.

Referring to FIG. 18, the electronic device 1800 according to an embodiment may include a display module 1810, a processor 1820, a memory 1830, and a power module 1840.

The processor 1820 may include at least one selected from a central processing unit (CPU), an application processor (AP), a graphics processing unit (GPU), a communication processor (CP), an image signal processor (ISP), and a controller.

The memory 1830 may store data information required for an operation of the processor 1820 or the display module 1810. When the processor 1820 executes an application stored in the memory 1830, image data signals and/or input control signals are transferred to the display module 1810, and the display module 1810 may process the received signals to output image information through a display screen.

The power module 1840 can include a power supply module, such as a power adapter or a battery device, and a power conversion module that converts the power supplied by the power supply module to generate the power required for an operation of the electronic device 1800.

At least one of the above-described components of the electronic device 1800 may be included in the display device 100 (see FIG. 1) according to the above-described embodiments. Additionally, one or more of individual modules that are functionally included in one module may be included in the display device 100 and individual modules other than the one or more of the individual modules may be provided separately from the display device 100. For example, the display device 100 may include a display module 1810, while the processor 1820, the memory 1830, and the power module 1840 may be provided in the form of other devices in the electronic device 1800 other than the display device.

In an embodiment, the power module 1840 may include the power supply circuit 150 (see FIG. 1) described above.

In an embodiment, the processor 1820 may include the host HST (see FIG. 1) described above.

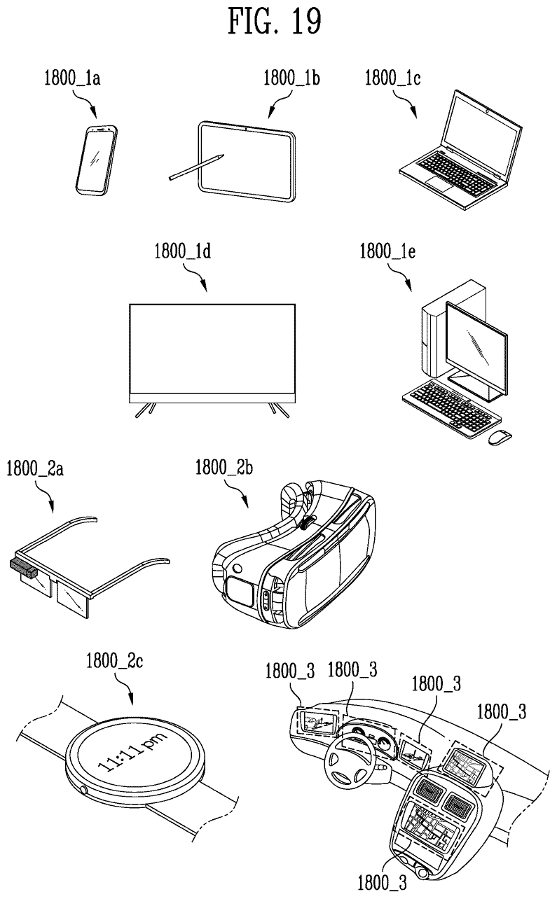

FIG. 19 shows schematic diagrams of electronic devices according to various embodiments of the present disclosure.

Referring to FIG. 19, examples of various electronic devices to which a display device according to embodiments of the present disclosure may include electronic devices for displaying images, such as a smartphone 1800_1a, a tablet personal computer (PC) 1800_1b, a laptop 1800_1c, a television 1800_1d, or a desk monitor 1800_1e, as well as wearable electronic devices including display modules such as smart glasses 1800_2a, a head-mounted display 1800_2b, or a smart watch 1800_2c, and automotive electronic devices 1800_3 including display modules such as an automotive dashboard, a center fascia, a center information display (CID) placed on a dashboard, or a room mirror display.

In the display device and the electronic device including the display device according to embodiments of the present disclosure, as described above, it is possible to improve visibility and display an image at various refresh frame rates with a narrow bezel.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A display device comprising:
clock wirings arranged in a first direction, wherein each of the clock wirings includes a first metal layer and a second metal layer vertically overlapping the first metal layer, and clock signals are input to the clock wirings;
side signal wirings including the first metal layer extending in a second direction crossing the first direction, and located adjacent to the clock wirings in the first direction; and
stage circuits located adjacent to the side signal wirings in the first direction, and connected to the clock wirings and the side signal wirings,
wherein the second metal layer of at least one of the clock wirings is bent at least once in a third direction opposite to the first direction to overlap an opening defined through the first metal layer.

2. The display device of claim 1, wherein an N-th stage circuit of the stage circuits includes:
an N-th scan driving integrated circuit; and
an N-th sense driving integrated circuit, wherein N is an integer greater than or equal to 1, and
wherein the clock wirings include:
first to sixth clock wirings connected to the N-th stage circuit; and
thirteenth to eighteenth clock wirings connected to the N-th stage circuit.

3. The display device of claim 2, wherein the first to sixth clock wirings are sequentially arranged in the first direction to be adjacent to each other, and
wherein the second metal layer of the first clock wiring extends in the second direction, is bent for a first time, and extends in the first direction.

4. The display device of claim 3, wherein the second metal layer of the third clock wiring
extends in the second direction, and is bent for a first time to extend in the third direction,
extends in the third direction, and is bent for a second time to extend in the second direction, and
extends in the second direction, and is bent for a third time to extend in the first direction.

5. The display device of claim 4, wherein a region of the second metal layer of the third clock wiring, which is bent for the second time and extends in the second direction, vertically overlaps an opening defined through the first metal layer of the second clock wiring.

6. The display device of claim 4, wherein the second metal layer of the fifth clock wiring
extends in the second direction, and is bent for a first time to extend in the third direction;
extends in the third direction, and is bent for a second time to extend in the second direction; and
extends in the second direction, and is bent for a third time to extend in the first direction.

7. The display device of claim 6, wherein a region of the second metal layer of the third clock wiring which is bent for the first time and extends in the third direction, and a region of the second metal layer of the fifth clock wiring which is bent for the first time and extends in the third direction are located adjacent to each other in the first direction.

8. The display device of claim 6, wherein a region of the second metal layer of the fifth clock wiring which is bent for the second time and extends in the second direction vertically overlaps an opening defined through the first metal layer of the third clock wiring.

9. The display device of claim 4, wherein a length of a region of the second metal layer of the first clock wiring which is bent for the first time and extends in the first direction is the same as a sum of:
a length of a region of the second metal layer of the third clock wiring which is bent for the first time and extends in the third direction; and
a length of a region of the second metal layer of the third clock wiring which is bent for the third time and extends in the first direction.

10. The display device of claim 3, wherein the second metal layer of the second clock wiring extends in a direction opposite to the second direction, and is bent for a first time to extend in the second direction.

11. The display device of claim 2, wherein an (N+1)-th stage circuit among the above stage circuits includes:
an (N+1)-th scan driving integrated circuit; and
an (N+1)-th sense driving integrated circuit, wherein N is an integer greater than or equal to 1, and
wherein the clock wirings further includes:
seventh to twelfth clock wirings connected to the (N+1)-th stage circuit; and
nineteenth to twenty-fourth clock wirings connected to the (N+1)-th stage circuit.

12. The display device of claim 1, wherein the stage circuits include a plurality of output buffers which outputs the clock signals input to the clock wirings, and
wherein at least two of transistors for controlling each of the plurality of output buffers are controlled in response to a voltage applied to one node.

13. An electronic device comprising:
a host which outputs a control signal and first image data; and
a display device which displays an image based on the control signal and the first image data,
wherein the display device comprises:
clock wirings sequentially arranged in a first direction, wherein each of the clock wirings includes a first metal layer and a second metal layer vertically overlapping the first metal layer, and clock signals provided based on the control signal is input to the clock wirings;
side signal wirings including the first metal layer extending in a second direction crossing the first direction, and located adjacent to the clock wirings in the first direction; and
stage circuits located adjacent to the side signal wirings in the first direction, and connected to the clock wirings and the side signal wirings,
wherein the second metal layer of at least one of the clock wirings is bent at least once in a third direction opposite to the first direction to overlap an opening defined through the first metal layer.

14. A display device comprising:
clock wirings sequentially arranged in a first direction, wherein each of the clock wirings includes a first metal layer and a second metal layer vertically overlapping the first metal layer, wherein clock signals are input to the clock wirings;
side signal wirings including the first metal layer extending in a second direction crossing the first direction, and located adjacent to the clock wirings in the first direction; and
stage circuits located adjacent to the side signal wirings in the first direction, and connected to the clock wirings and the side signal wirings,
wherein a first clock wiring of the clock wirings has a first longitudinal width, and
wherein a second clock wiring of the clock wirings, which is located closer to the stage circuits than the first clock wiring is, has a second longitudinal width which is smaller than the first longitudinal width.

15. The display device of claim 14, wherein an N-th stage circuit of the stage circuits includes:
an N-th scan driving integrated circuit; and
an N-th sense driving integrated circuit, wherein N is an integer greater than or equal to 1, and
wherein the clock wirings includes:
first and second clock wirings connected to the N-th stage circuit; and
thirteenth and fourteenth clock wirings connected to the N-th stage circuit.

16. The display device of claim 15, wherein the second metal layer of each of the first clock wiring and the second clock wiring, extends in the second direction, and is bent for a first time to extend in the first direction, and
wherein a length of a region in which the first clock wiring extends in the second direction is longer than a length of a region in which the second clock wiring extends in the second direction.

17. The display device of claim 16, wherein a region in which the first clock wiring extends in the first direction has a first longitudinal width, and
wherein a region in which the second clock wiring extends in the first direction has the second longitudinal width.

18. The display device of claim 17, wherein the second metal layer of each of the thirteenth clock wiring and the fourteenth clock wiring extends in the second direction, and is bent for a first time to extend in the first direction, and
wherein a length of a region in which the thirteenth clock wiring extends in the first direction is longer than a length of a region in which the fourteenth clock wiring extends in the first direction.

19. The display device of claim 18, wherein a region in which the thirteenth clock wiring extends in the first direction has the first longitudinal width, and
wherein a region in which the fourteenth clock wiring extends in the first direction has the second longitudinal width.

20. The display device of claim 14, wherein one of the side signal wirings
has a first lateral width in a region overlapping the first clock wiring of the clock wirings, and
have a second lateral width larger than the first lateral width in a region overlapping the second clock wiring of the clock wirings.
